(19) United States
(12) Patent Application Publication
(10) Pub. No.: US 2026/0362911 A1
(43) Pub. Date: Nov. 12, 2026

(54) DISPLAY PANEL

(71) Applicant: Hubei Yangtze Industrial Innovation Center Of Advanced Display Co., Ltd., Wuhan (CN)

(72) Inventor: Yi Wang, Wuhan (CN)

(73) Assignee: Hubei Yangtze Industrial Innovation Center Of Advanced Display Co., Ltd., Wuhan (CN)

(21) Appl. No.: 19/673,318

(22) Filed: May 11, 2026

(30) Foreign Application Priority Data
Dec. 31, 2025 (CN) 202512059157.2

(51) Int. Cl. H10K 59/122; H10K 59/35; H10K 59/80

(52) U.S. Cl. CPC H10K 59/122; H10K 59/353; H10K 59/8792

(57) ABSTRACT

Provided is a display panel. The display panel includes a first light-emitting element, a first light-emitting portion, and a second light-emitting portion, and the second light-emitting portion surrounds at least part of the first light-emitting portion; a maximum light-emitting viewing angle of the first light-emitting element is greater than a maximum light-emitting viewing angle of the first light-emitting portion, and the minimum light-emitting viewing angle of the second light-emitting portion is greater than the minimum light-emitting viewing angle of the first light-emitting element and the first light-emitting portion; in a sharing mode, the first light-emitting element, the first light-emitting portion, and the second light-emitting portion all emit light; and in a privacy mode, the first light-emitting element and the first light-emitting portion emit light, and the second light-emitting portion does not emit light.

### CROSS-REFERENCE TO RELATED APPLICATION(S)

This application claims priority of a Chinese Patent Application filed with China National Intellectual Property Administration (CNIPA) on Dec. 31, 2025, with application No. 202512059157.2, the disclosure of which is incorporated herein by reference in its entirety.

### TECHNICAL FIELD

The present application relates to the technical field of display panels and, in particular, to a display panel.

### BACKGROUND

With the development of display technology and the emergence of various display technologies, various display devices have been developed, including liquid crystal display panels, organic light-emitting display panels, plasma display panels, and electrophoretic display panels.

On this basis, users have increasingly strong awareness of personal privacy protection when using the display devices. How to ensure the anti-peeping performance of the display devices becomes a research hotspot.

### SUMMARY

Embodiments of the present application provide a display panel and a display device to improve the anti-peeping effect of the display panel at a large viewing angle.

In a first aspect, embodiments of the present application provide a display panel. The display panel includes a substrate, multiple light-emitting elements on a side of the substrate, a light-shielding structure, and a pixel defining layer; the multiple light-emitting elements include first light-emitting elements and second light-emitting elements, a second light-emitting element includes a first light-emitting portion and a second light-emitting portion, and the second light-emitting portion surrounds at least part of the first light-emitting portion; the light-shielding structure is located on a side of the light-emitting elements facing away from the substrate; the light-shielding structure includes a first opening, a second opening, and a first light-shielding portion, and along a direction perpendicular to a plane where the substrate is located, the first opening at least partially overlaps a first light-emitting element, the second opening at least partially overlaps the first light-emitting portion, and the first light-shielding portion at least partially overlaps the second light-emitting portion; the pixel defining layer includes a first pixel opening and a second pixel opening, the second pixel opening includes a first pixel opening portion and a second pixel opening portion, and the second pixel opening portion surrounds at least part of the first pixel opening portion; at least part of the first light-emitting element is located within the first pixel opening; at least part of the first light-emitting portion is located within the first pixel opening portion; and along a direction parallel to the plane where the substrate is located, the minimum distance between an edge of the first opening and an edge of the first pixel opening is d1, the minimum distance between an edge of the second opening and an edge of the first pixel opening portion is d2, and d1>d2; display modes of the display panel include a sharing mode and a privacy mode; in the sharing mode, the first light-emitting element, the first light-emitting portion, and the second light-emitting portion all emit light; and in the privacy mode, the first light-emitting element and the first light-emitting portion emit light, and the second light-emitting portion does not emit light.

In a second aspect, embodiments of the present application provide a display panel. The display panel includes a substrate and multiple light-emitting elements on a side of the substrate; the multiple light-emitting elements include first light-emitting elements and second light-emitting elements, a second light-emitting element includes a first light-emitting portion and a second light-emitting portion, and the second light-emitting portion surrounds at least part of the first light-emitting portion; the maximum light-emitting viewing angle of a first light-emitting element is greater than the maximum light-emitting viewing angle of the first light-emitting portion, and the minimum light-emitting viewing angle of the second light-emitting portion is greater than the minimum light-emitting viewing angle of the first light-emitting element and the minimum light-emitting viewing angle of the first light-emitting portion; display modes of the display panel include a sharing mode and a privacy mode; in the sharing mode, the first light-emitting element, the first light-emitting portion, and the second light-emitting portion all emit light; and in the privacy mode, the first light-emitting element and the first light-emitting portion emit light, and the second light-emitting portion does not emit light.

In a third aspect, embodiments of the present application provide a display device. The display device includes the display panel of the first aspect or the second aspect.

### BRIEF DESCRIPTION OF DRAWINGS

To illustrate technical solutions in embodiments of the present application more clearly, the drawings used in the description of the embodiments of the present application are described below briefly. Apparently, the drawings described below illustrate merely part of embodiments of the present application, and those of ordinary skill in the art may obtain other drawings based on the embodiments of the present application and these drawings on the premise that no creative work is done.

FIG. 1 is a structure diagram of a display panel according to embodiments of the present application.

FIG. 2 is a sectional view of the display panel shown in FIG. 1 along line A-A′.

FIG. 3 is a partial structure diagram of the display panel shown in FIG. 1.

FIG. 4 is another partial structure diagram of the display panel shown in FIG. 1.

FIG. 5 is another partial structure diagram of the display panel shown in FIG. 1.

FIG. 6 is another structure diagram of a display panel according to embodiments of the present application.

FIG. 7 is another structure diagram of a display panel according to embodiments of the present application.

FIG. 8 is another structure diagram of a display panel according to embodiments of the present application.

FIG. 9 is another structure diagram of a display panel according to embodiments of the present application.

FIG. 10 is another structure diagram of a display panel according to embodiments of the present application.

FIG. 11 is another structure diagram of a display panel according to embodiments of the present application.

FIG. 12 is another structure diagram of a display panel according to embodiments of the present application.

FIG. 13 is a schematic diagram of an arrangement of light-emitting elements of a first color according to embodiments of the present application.

FIG. 14 is another schematic diagram of an arrangement of light-emitting elements of a first color according to embodiments of the present application.

FIG. 15 is a schematic diagram of an arrangement of light-emitting elements of a second color according to embodiments of the present application.

FIG. 16 is another schematic diagram of an arrangement of light-emitting elements of a second color according to embodiments of the present application.

FIG. 17 is a schematic diagram of an arrangement of light-emitting elements of a third color according to embodiments of the present application.

FIG. 18 is another schematic diagram of an arrangement of light-emitting elements of a third color according to embodiments of the present application.

FIG. 19 is a schematic diagram of an arrangement of light-emitting elements whose light emission is visible at a large viewing angle in a privacy mode of the display panel corresponding to FIG. 1.

FIG. 20 is a schematic diagram of an arrangement of light-emitting elements whose light emission is visible at a large viewing angle in a privacy mode of the display panel corresponding to FIG. 6.

FIG. 21 is a schematic diagram of an arrangement of light-emitting elements whose light emission is visible at a large viewing angle in a privacy mode of the display panel corresponding to FIG. 7.

FIG. 22 is a schematic diagram of an arrangement of light-emitting elements whose light emission is visible at a large viewing angle in a privacy mode of the display panel corresponding to FIG. 8.

FIG. 23 is a schematic diagram of an arrangement of light-emitting elements whose light emission is visible at a large viewing angle in a privacy mode of the display panel corresponding to FIG. 9.

FIG. 24 is a schematic diagram of an arrangement of light-emitting elements whose light emission is visible at a large viewing angle in a privacy mode of the display panel corresponding to FIG. 10.

FIG. 25 is a schematic diagram of an arrangement of light-emitting elements whose light emission is visible at a large viewing angle in a privacy mode of the display panel corresponding to FIG. 11.

FIG. 26 is a schematic diagram of an arrangement of light-emitting elements whose light emission is visible at a large viewing angle in a privacy mode of the display panel corresponding to FIG. 12.

FIG. 27 is a structure diagram of a second light-emitting element according to embodiments of the present application.

FIG. 28 is a structure diagram of two adjacent second light-emitting elements emitting light of the same color according to embodiments of the present application.

FIG. 29 is another sectional view of the display panel shown in FIG. 1 along line A-A′.

FIG. 30 is a schematic diagram of connections of a fourth pixel circuit with a first light-emitting portion and a second light-emitting portion according to embodiments of the present application.

FIG. 31 is another sectional view of the display panel shown in FIG. 1 along line A-A′.

FIG. 32 is another sectional view of the display panel shown in FIG. 1 along line A-A′.

FIG. 33 is a structure diagram of a display device according to embodiments of the present application.

### DETAILED DESCRIPTION

The present application is further described in detail below in conjunction with the drawings and embodiments. It is to be understood that the embodiments described herein are intended to illustrate the present application and not to limit the present application. Additionally, it is to be noted that for ease of description, only part, not all, of structures related to the present application are illustrated in the drawings.

In the description of the present application, terms “joined”, “connected”, and “fixed” are to be understood in a broad sense unless otherwise expressly specified and limited. For example, the term “connected” may refer to “fixedly connected”, “detachably connected”, or “integrated”, may refer to “mechanically connected” or “electrically connected”, or may refer to “connected directly”, “connected indirectly through an intermediary”, “connected inside two elements”, or an interaction relationship between two elements. For those of ordinary skill in the art, specific meanings of the preceding terms in the present disclosure may be understood based on specific situations.

In the present application, unless otherwise expressly specified and limited, when a first feature is described as “above” or “below” a second feature, the first feature may be in direct contact with the second feature, or the first feature may be in contact with the second feature via another intermediate feature. Moreover, when the first feature is described as “on”, “above”, or “over” the second feature, the first feature is right on, above, or over the second feature, the first feature is obliquely on, above, or over the second feature, or the first feature is simply at a higher level than the second feature. When the first feature is described as “under”, “below”, or “underneath” the second feature, the first feature is right under, below, or underneath the second feature, the first feature is obliquely under, below, or underneath the second feature, or the first feature is simply at a lower level than the second feature.

In the description of embodiments, orientations or position relationships indicated by terms such as “upper”, “lower”, and “right” are based on the drawings. These orientations or position relationships are intended to facilitate description and simplify operations and not to indicate or imply that a device or element referred to must have such particular orientations or must be configured or operated in such particular orientations. Thus, these orientations or position relationships are not to be construed as limiting the present application. Moreover, terms “first” and “second” are used for the distinguishing purpose in description and have no special meanings.

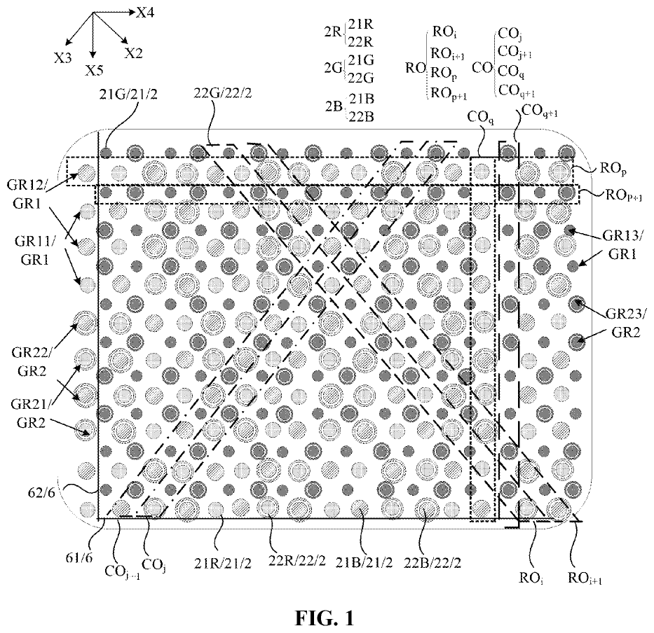

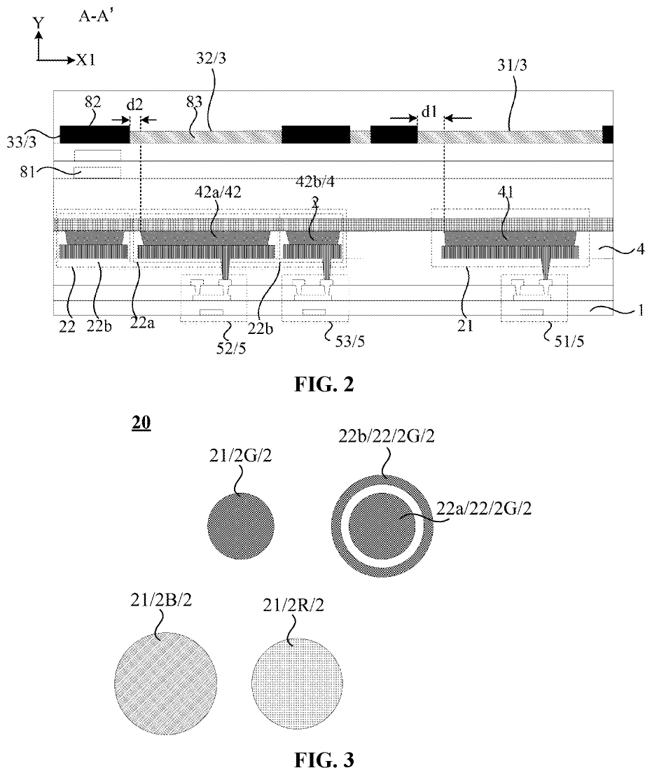

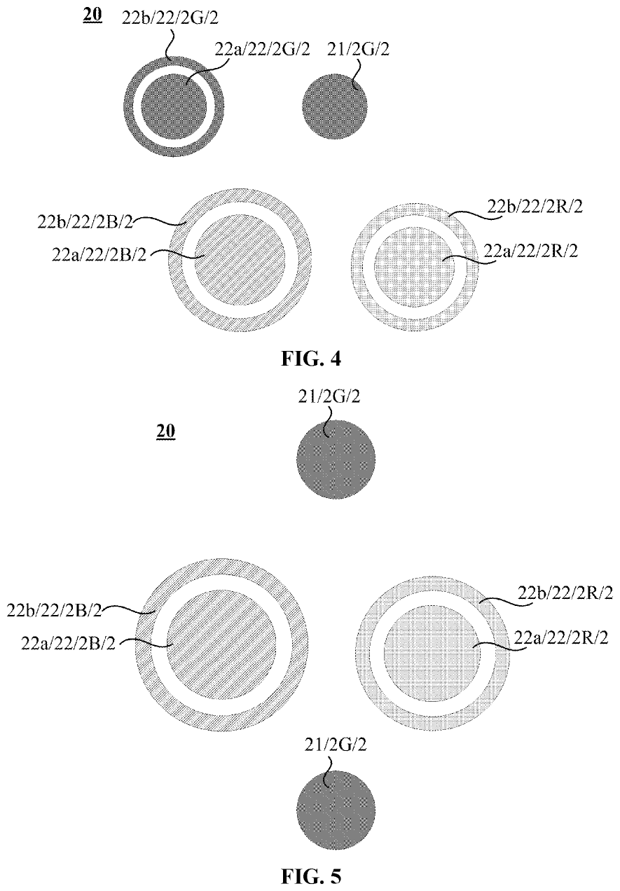

FIG. 1 is a structure diagram of a display panel according to embodiments of the present application. FIG. 2 is a sectional view of the display panel shown in FIG. 1 along line A-A′. FIG. 3 is a partial structure diagram of the display panel shown in FIG. 1. FIG. 4 is another partial structure diagram of the display panel shown in FIG. 1. FIG. 5 is another partial structure diagram of the display panel shown in FIG. 1. As shown in FIGS. 1 to 5, the display panel according to the embodiments of the present application includes a substrate 1, multiple light-emitting elements 2 on a side of the substrate, a light-shielding structure 3, and a pixel defining layer 4; the multiple light-emitting elements 2 include first light-emitting elements 21 and second light-emitting elements 22, a second light-emitting element 22 includes a first light-emitting portion 22a and a second light-emitting portion 22b, and the second light-emitting portion 22b surrounds at least part of the first light-emitting portion 22a; the light-shielding structure 3 is located on a side of the light-emitting elements 2 facing away from the substrate 1; the light-shielding structure 3 includes a first opening 31, a second opening 32, and a first light-shielding portion 33, and along a direction perpendicular to a plane where the substrate 1 is located (the direction Y shown in the figure), the first opening 31 at least partially overlaps a first light-emitting element 21, the second opening 32 at least partially overlaps the first light-emitting portion 22a, and the first light-shielding portion 33 at least partially overlaps the second light-emitting portion 22b; the pixel defining layer 4 includes a first pixel opening 41 and a second pixel opening 42, the second pixel opening 42 includes a first pixel opening portion 42a and a second pixel opening portion 42b, and the second pixel opening portion 42b surrounds at least part of the first pixel opening portion 42a; at least part of the first light-emitting element 21 is located within the first pixel opening 41; at least part of the first light-emitting portion 22a is located within the first pixel opening portion 42a; and along a direction parallel to the plane where the substrate 1 is located (the direction X1 shown in the figure), the minimum distance between an edge of the first opening 31 and an edge of the first pixel opening 41 is d1, the minimum distance between an edge of the second opening 32 and an edge of the first pixel opening portion 42a is d2, and d1>d2. Display modes of the display panel include a sharing mode and a privacy mode; in the sharing mode, the first light-emitting element 21, the first light-emitting portion 22a, and the second light-emitting portion 22b all emit light; and in the privacy mode, the first light-emitting element 21 and the first light-emitting portion 22a emit light, and the second light-emitting portion 22b does not emit light.

As shown in FIGS. 1 and 2, the display panel includes the substrate 1 and the multiple light-emitting elements 2 on the side of the substrate 1. The light-emitting elements 2 may include light-emitting elements of different colors, for example, at least one of red light-emitting elements, green light-emitting elements, blue light-emitting elements, or white light-emitting elements. Moreover, the light-emitting element 2 may be one of an organic light-emitting diode, a micro organic light-emitting diode, or a micro light-emitting diode. In an example in which the light-emitting element 2 is the organic light-emitting diode, the light-emitting element 2 may include a first electrode, a second electrode, and an organic compound layer located between the first electrode and the second electrode. The organic compound layer may include, but is not limited to, a hole injection layer, a hole transport layer, an electron blocking layer, a light-emitting layer, an electron transport layer, a hole blocking layer, and an electron injection layer. Alternatively, the organic compound layer may also include a charge generation layer, such as a p-type charge generation layer or an n-type charge generation layer. When a voltage is applied between the first electrode and the second electrode of the organic light-emitting diode, holes transported through the hole transport layer and electrons transported through the electron transport layer move to the light-emitting layer to form excitons, resulting in emission of visible light from the light-emitting layer.

Further, with continued reference to FIG. 2, the display panel further includes the pixel defining layer 4, the pixel defining layer 4 is provided with multiple pixel openings, and each pixel opening is used for defining a light-emitting region of the light-emitting element. Specifically, the light-emitting elements 2 include the first light-emitting elements 21 and the second light-emitting elements 22, the second light-emitting element 22 includes the first light-emitting portion 22a and the second light-emitting portion 22b, and the second light-emitting portion 22b surrounds at least part of the first light-emitting portion 22a. Correspondingly, the pixel defining layer 4 includes the first pixel opening 41 and the second pixel opening 42, the second pixel opening 42 includes the first pixel opening portion 42a and the second pixel opening portion 42b, and the second pixel opening portion 42b surrounds at least part of the first pixel opening portion 42a. At least part of the first light-emitting element 21 is located within the first pixel opening 41. That is, at least part of a light-emitting film of the first light-emitting element 21 is located within the first pixel opening 41, and the first pixel opening 41 defines at least part of a light-emitting region of the first light-emitting element 21. At least part of the first light-emitting portion 22a is located within the first pixel opening portion 42a. That is, at least part of a light-emitting film of the first light-emitting portion 22a is located within the first pixel opening portion 42a, and the first pixel opening portion 42a defines at least part of a light-emitting region of the first light-emitting portion 22a. At least part of the second light-emitting portion 22b is located within the second pixel opening portion 42b. That is, at least part of a light-emitting film of the second light-emitting portion 22b is located within the second pixel opening portion 42b, and the second pixel opening portion 42b defines at least part of a light-emitting region of the second light-emitting portion 22b. The pixel defining layer 4 and the pixel openings are disposed, and the pixel opening defines at least part of the light-emitting film of the light-emitting element so that crosstalk between different light-emitting elements can be reduced, and a light emission contrast between different light-emitting elements can be improved.

Further, with continued reference to FIG. 2, the display panel further includes the light-shielding structure 3 located on the light emission side of the light-emitting elements, and the light-shielding structure 3 is used for adjusting light-emitting viewing angles of the light-emitting elements 2. Specifically, the light-shielding structure 3 includes the first opening 31, the second opening 32, and the first light-shielding portion 33, and along the direction perpendicular to the plane where the substrate 1 is located, the first opening 31 at least partially overlaps the first light-emitting element 21 so that at least part of light from the first light-emitting element 21 can be emitted through the first opening 31, the second opening 32 at least partially overlaps the first light-emitting portion 22a so that at least part of light from the first light-emitting portion 22a can be emitted through the second opening 32, and the first light-shielding portion 33 at least partially overlaps the second light-emitting portion 22b so that at least part of light emitted by the second light-emitting portion 22b at a normal viewing angle or a small viewing angle is shielded by the first light-shielding portion 33 and cannot be emitted and at least part of light emitted by the second light-emitting portion 22b at a large viewing angle can be emitted through the second opening 32. It is to be understood that the viewing angle in the embodiments of the present application may be understood as an acute angle formed between a propagation direction of light emitted by the light-emitting element and the thickness direction of the display panel. The light emitted at the normal viewing angle or small viewing angle may be understood as that the acute angle formed between the direction of the light emitted by the light-emitting element and the thickness direction of the display panel is relatively small, for example, 0°, 5°, or 10°, or the formed acute angle is less than 30°. The light emitted at the large viewing angle may be understood as that the acute angle formed between the direction of the light emitted by the light-emitting element and the thickness direction of the display panel is relatively large, for example, 50°, 60°, or 70°, or the formed acute angle is greater than or equal to 45°. In the embodiments of the present application, the small viewing angle and the large viewing angle are relative concepts. The magnitude of the small viewing angle or the large viewing angle is not numerically limited in the embodiments of the present application.

Further, with continued reference to FIG. 2, along the direction perpendicular to the plane where the substrate 1 is located, the first opening 31 covers the first pixel opening 41, and the second opening 32 covers the first pixel opening portion 42a, thereby ensuring that a relatively large amount of light emitted by the first light-emitting element 21 can be emitted through the first opening 31, and that a relatively large amount of light emitted by the first light-emitting portion 22a can be emitted through the second opening 32. Moreover, along the direction parallel to the plane where the substrate 1 is located (the direction X1 shown in the figure), the minimum distance d1 between the edge of the first opening 31 and the edge of the first pixel opening 41 and the minimum distance d2 between the edge of the second opening 32 and the edge of the first pixel opening portion 42a satisfy that d1>d2. That is, the distance between the edge of the first opening 31 and the edge of the first pixel opening 41 is larger, and the distance between the edge of the second opening 32 and the edge of the first pixel opening portion 42a is smaller so that light emitted by the first light-emitting element 21 at a relatively large viewing angle can be emitted through the first opening 31 without being shielded by a light-shielding region outside the first opening 31, while light emitted by the first light-emitting portion 22a at a relatively large viewing angle is shielded by a light-shielding region outside the second opening 32 and cannot be emitted through the second opening 32. That is, through the light-shielding structure 3, the maximum light-emitting viewing angle of the first light-emitting element 21 is greater than the maximum light-emitting viewing angle of the first light-emitting portion 22a. Further, the first light-shielding portion 33 at least partially overlaps the second light-emitting portion 22b so that at least part of the light emitted by the second light-emitting portion 22b at the normal viewing angle is shielded by the first light-shielding portion 33 and cannot be emitted, and at least part of the light emitted by the second light-emitting portion 22b at the large viewing angle can be emitted through the second opening 32. Moreover, the second light-emitting portion 22b surrounds the first light-emitting portion 22a. In this manner, a reasonable setting of the light emission timing of the first light-emitting portion 22a and the second light-emitting portion 22b can ensure that the second light-emitting element 22 can achieve light emission at both the small viewing angle and the large viewing angle. It is to be noted that specific values of d1 and d2 are not limited in the embodiments of the present application, and the values of d1 and d2 may be reasonably set according to a panel size and a display resolution, for example, 0<d2<2 μm, and d1>2 μm.

Specifically, the display modes of the display panel include the sharing mode and the privacy mode. In the sharing mode, the first light-emitting element 21, the first light-emitting portion 22a, and the second light-emitting portion 22b all emit light so that the light emitted by the first light-emitting element 21 is visible at both the normal viewing angle and the large viewing angle, the light emitted by the first light-emitting portion 22a is visible at the normal viewing angle, and the light emitted by the second light-emitting portion 22b is visible at the large viewing angle. That is, the light emitted by the first light-emitting element 21 and the light emitted by the second light-emitting element 22 are visible at both the normal viewing angle and the large viewing angle, thereby achieving normal display at different viewing angles. In the privacy mode, the first light-emitting element 21 and the first light-emitting portion 22a emit light, and the second light-emitting portion 22b does not emit light so that the light emitted by the first light-emitting element 21 is visible at both the normal viewing angle and the large viewing angle, and the light emitted by the first light-emitting portion 22a is visible at the normal viewing angle, ensuring that the display panel has normal display content and display brightness at the normal viewing angle and achieves normal display. No light emitted by the second light-emitting portion 22b is visible at the large viewing angle, that is, the light emitted by the second light-emitting element 22 is partially missing at the large viewing angle, resulting in a color shift due to partial light missing at the large viewing angle. Thus, information displayed at the large viewing angle is blurred or disordered, achieving the confidentiality of display information. It is to be understood that anti-peeping is to prevent information from being observed at the large viewing angle and prevent information from being peeped or seen at the large viewing angle, thereby achieving visibility within a narrow viewing angle and invisibility at the large viewing angle.

Further, the display panel includes multiple light-emitting element groups 20, and a light-emitting element group 20 includes at least one first light-emitting element 21 and at least one second light-emitting element 22. In this manner, in the sharing mode, the light emitted by the first light-emitting element 21 and the light emitted by the second light-emitting element 22 in the same light-emitting element group 20 are visible at both the normal viewing angle and the large viewing angle, achieving normal display in the sharing mode. In the privacy mode, the same light-emitting element group 20 includes at least one second light-emitting portion 22b emitting no light. The second light-emitting portion 22b emitting no light can ensure that the light-emitting element group 20 and another light-emitting element group that also uses the second light-emitting portion 22b in this light-emitting element group both have the missing second light-emitting portion 22b, ensuring that at least part of the light-emitting element groups suffer display color shifts at the large viewing angle due to the missing second light-emitting portion 22b, ensuring that display information of at least part of the light-emitting element groups 20 is blurred or disordered at the large viewing angle, achieving the confidentiality of display information of at least part of the light-emitting element groups at the large viewing angle, achieving the confidentiality of display information of the entire display panel, and implementing the anti-peeping function.

Further, as shown in FIGS. 3 to 5, the light-emitting element group 20 may include one light-emitting element of a first color 2R, one light-emitting element of a second color 2B, and two light-emitting elements of a third color 2G. That is, the light-emitting element group 20 may have an RGBG structure. In this manner, in the same light-emitting element group 20 among at least part of the light-emitting element groups 20, one to three second light-emitting portions 22b emitting no light are present in the privacy mode. The second light-emitting portions 22b emitting no light can ensure that the light-emitting element group 20 and another light-emitting element group that also uses the second light-emitting portions 22b in this light-emitting element group both have the missing second light-emitting portions 22b, thereby achieving the confidentiality of display information of at least part of the light-emitting element groups at the large viewing angle, achieving the confidentiality of display information of the entire display panel, and implementing the anti-peeping function. Moreover, as shown in FIGS. 3 to 5, the light-emitting element of the first color 2R, the light-emitting element of the second color 2B, and the light-emitting elements of the third color 2G in the same light-emitting element group 20 may be arranged in different manners, which are not limited in the embodiments of the present application.

It is to be noted that as shown in FIGS. 1 and 2, regions of the light-shielding structure 3 other than the first opening 31 and the second opening 32 are all regions where light-shielding portions in the light-shielding structure are disposed. To illustrate the light-emitting elements clearly, the light-shielding structure is not shown in FIG. 1. For the light-shielding structure, reference may be made to FIG. 2. Moreover, the light-shielding structure is not shown in each of the subsequent top views of the display panel, and the details are not repeated hereinafter.

To sum up, the display panel according to the embodiments of the present application includes the light-emitting elements, the light-shielding structure, and the pixel defining layer. A correspondence relationship between positions of the light-emitting elements, positions of openings and light-shielding portions in the light-shielding structure, and positions of pixel openings in the pixel defining layer is reasonably set so that the first light-emitting element performs normal light emission at both the normal viewing angle and the large viewing angle, the first light-emitting portion performs normal light emission at the normal viewing angle, and the second light-emitting portion performs normal light emission at the large viewing angle. Further, light emission timings of the light-emitting elements and the light-emitting portions in different display modes are set so that the display panel performs normal display at different viewing angles in the sharing mode, and part of display content is missing at the large viewing angle in the privacy mode, implementing the anti-peeping function. Moreover, each light-emitting element group includes at least one first light-emitting element and at least one second light-emitting element, ensuring that each light-emitting element group can achieve normal display in the sharing mode, and the display information of at least part of the light-emitting element groups is blurred or disordered at the large viewing angle in the privacy mode, achieving the confidentiality of display information of at least part of the light-emitting element groups at the large viewing angle, achieving the confidentiality of display information of the entire display panel, and implementing the anti-peeping function.

In one or more embodiments, with continued reference to FIGS. 1 and 3 to 5, for the first light-emitting element 21 and the second light-emitting element 22 having the same emitted color, a pixel opening area of the first light-emitting element 21 is S1, a pixel opening area of the first light-emitting portion 22a is S2, and a pixel opening area of the second light-emitting portion 22b is S3; where S1>S3, S2>S3, and 80% ≤S1/S2≤120%.

For the first light-emitting element 21 and the second light-emitting element 22 having the same emitted color, the pixel opening area S1 of the first light-emitting element 21, the pixel opening area S2 of the first light-emitting portion 22a, and the pixel opening area S3 of the second light-emitting portion 22b satisfy that S1>S3, and S2>S3. That is, the pixel opening area of the first light-emitting element 21 is greater than the pixel opening area of the second light-emitting portion 22b, and the pixel opening area of the first light-emitting portion 22a is greater than the pixel opening area of the second light-emitting portion 22b, that is, the first light-emitting element 21 and the first light-emitting portion 22a each have a larger light emission area. In this manner, in the sharing mode and the privacy mode, both the first light-emitting element 21 and the first light-emitting portion 22a can fully display the display content, achieving a good display effect and ensuring the normal display of the display panel.

Further, the pixel opening area S1 of the first light-emitting element 21 and the pixel opening area S2 of the first light-emitting portion 22a satisfy that 80% ≤S1/S2≤120%. That is, the pixel opening area of the first light-emitting element 21 is equal or similar to the pixel opening area of the first light-emitting portion 22a, ensuring that the first light-emitting element 21 and the first light-emitting portion 22a have the same or similar display effects in the sharing mode and the privacy mode and ensuring at least the display effect at the normal viewing angle.

Further, with continued reference to FIGS. 1 and 3 to 5, a shape of at least one of the first pixel opening 41, the first pixel opening portion 42a, or the second pixel opening 42 includes a circle.

As shown in FIGS. 1 and 3 to 5, the shape of at least one of the first pixel opening 41, the first pixel opening portion 42a, or the second pixel opening 42 includes the circle, ensuring that at least one of the first pixel opening 41, the first pixel opening portion 42a, or the second pixel opening 42 is regular in shape, avoiding optical diffraction due to a sharp angle, and improving the light emission and display effects of the display panel.

In one or more embodiments, as shown in FIGS. 1 and 3 to 5, the first pixel opening 41, the first pixel opening portion 42a, and the second pixel opening 42 may all be circular, ensuring that the light emission from the first pixel opening 41, the first pixel opening portion 42a, and the second pixel opening 42 can be prevented from optical diffraction to the maximum extent and fully ensuring the display effect of the display panel.

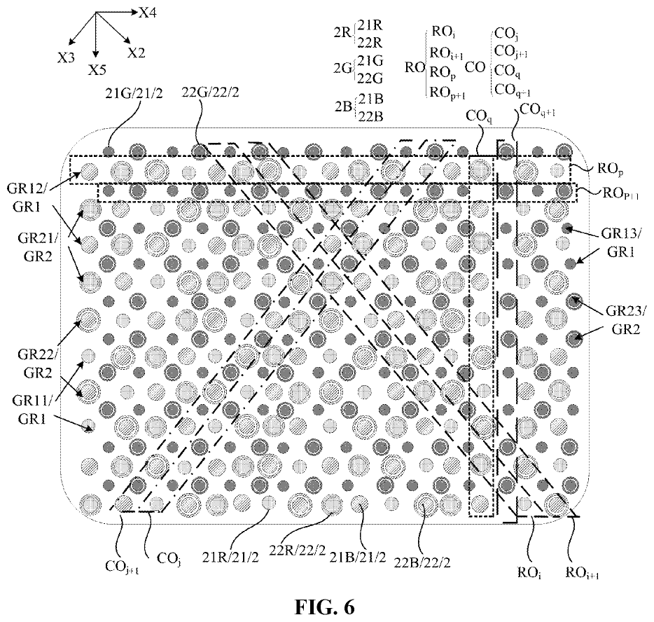

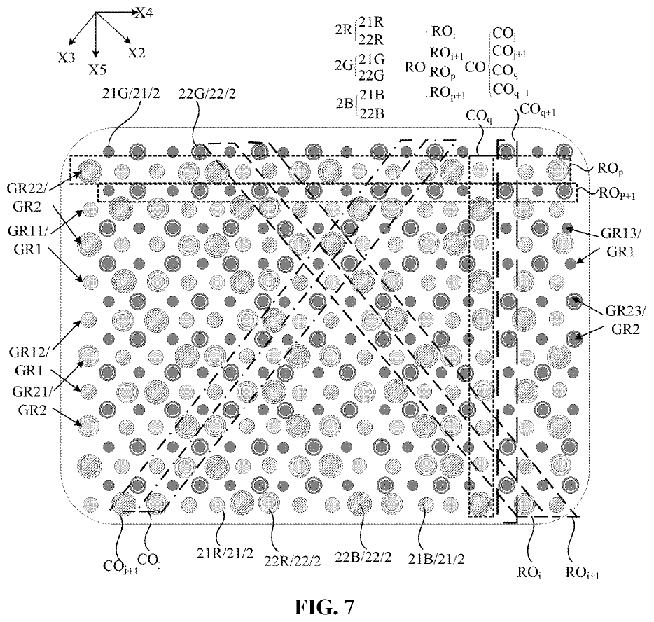

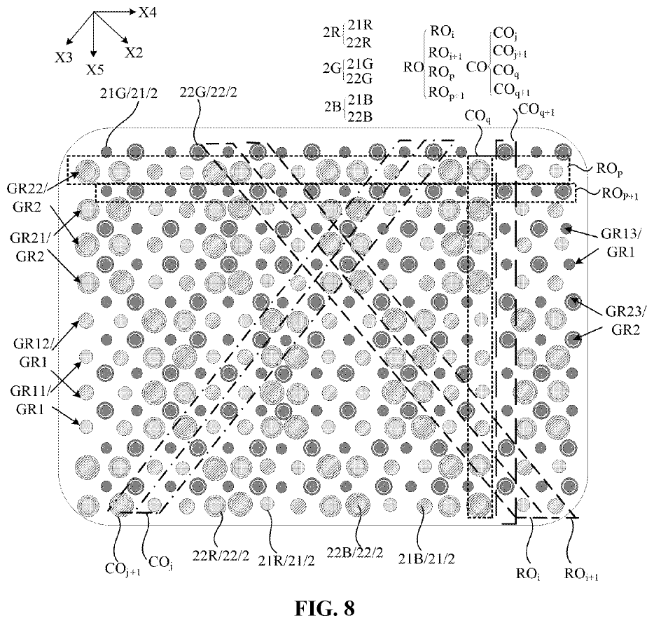

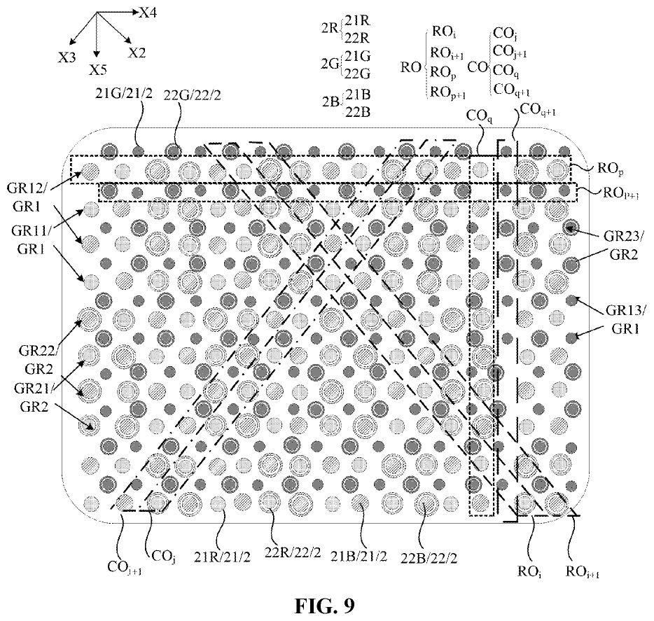

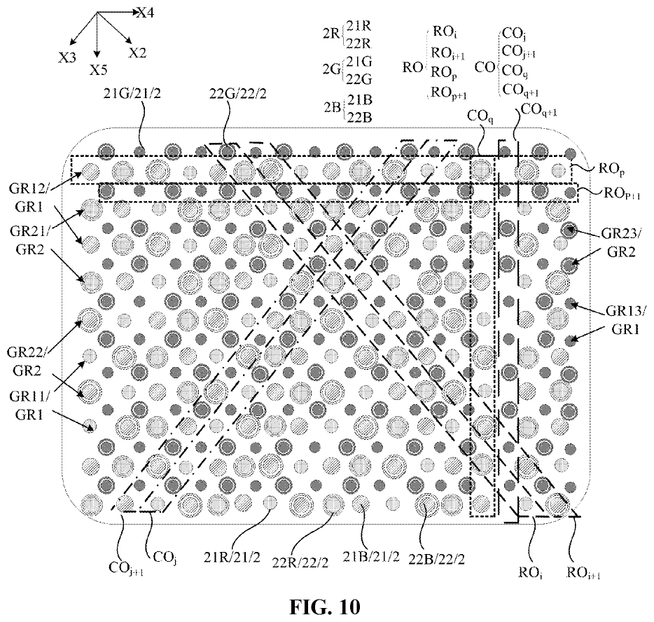

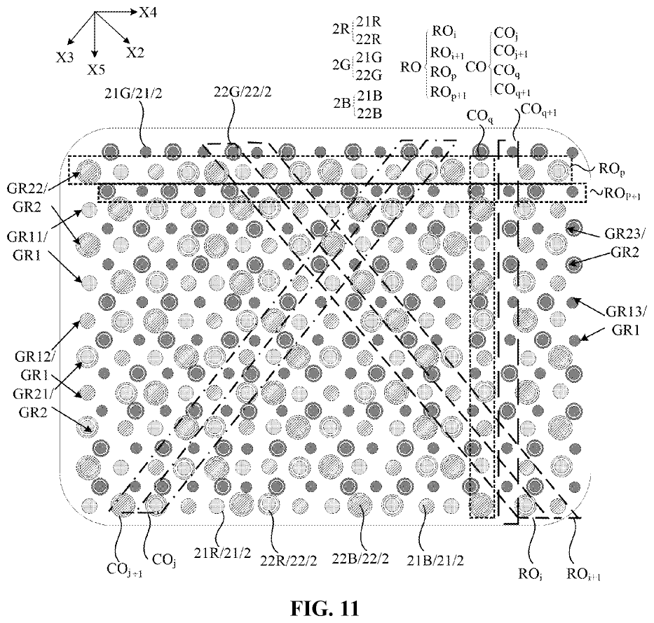

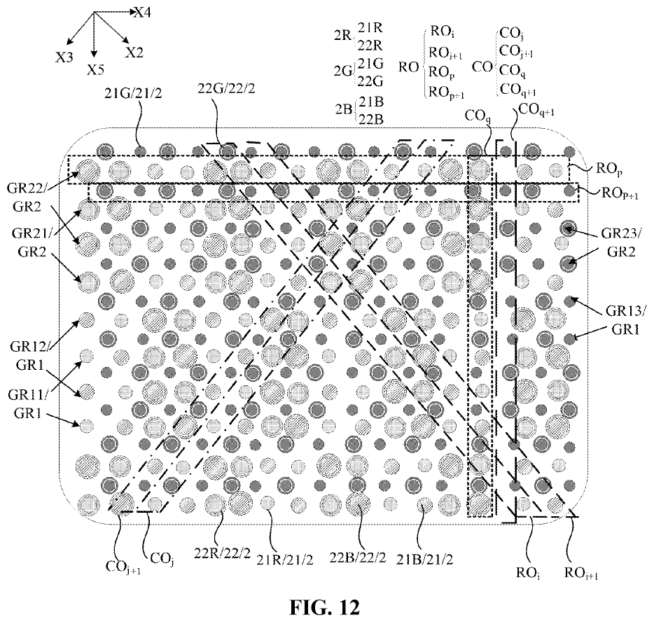

Based on the preceding embodiments, FIG. 6 is another structure diagram of a display panel according to embodiments of the present application, FIG. 7 is another structure diagram of a display panel according to embodiments of the present application, FIG. 8 is another structure diagram of a display panel according to embodiments of the present application, FIG. 9 is another structure diagram of a display panel according to embodiments of the present application, FIG. 10 is another structure diagram of a display panel according to embodiments of the present application, FIG. 11 is another structure diagram of a display panel according to embodiments of the present application, and FIG. 12 is another structure diagram of a display panel according to embodiments of the present application. As shown in FIGS. 1 and 6 to 12, the display panel further includes light-emitting elements of the first color 2R, light-emitting elements of the second color 2B, and light-emitting elements of the third color 2G; a light-emitting element of the first color 2R, a light-emitting element of the second color 2B, and a light-emitting element of the third color 2G are each one of a red light-emitting element, a blue light-emitting element, and a green light-emitting element and are different from each other; the display panel further includes multiple light-emitting element columns CO arranged along a first direction (the direction X2 shown in the figure, where the first direction X2 is used hereinafter as an example for description) and multiple light-emitting element rows RO arranged along a second direction (the direction X3 shown in the figure, where the second direction X3 is used hereinafter as an example for description), and the first direction X2 intersects the second direction X3. An i-th light-emitting element row ROᵢ includes light-emitting elements of the first color 2R and light-emitting elements of the third color 2G which are alternately arranged along the first direction X2; an (i+1)-th light-emitting element row ROᵢ₊₁ includes light-emitting elements of the second color 2B and light-emitting elements of the third color 2G which are alternately arranged along the first direction X2; a j-th light-emitting element column COⱼ includes light-emitting elements of the first color 2R and light-emitting elements of the third color 2G which are alternately arranged along the second direction X3; and a (j+1)-th light-emitting element column COⱼ₊₁ includes light-emitting elements of the second color 2B and light-emitting elements of the third color 2G which are alternately arranged along the second direction X3, where i and j are each a positive integer.

FIGS. 1 and 6 to 12 show multiple arrangements of the first light-emitting elements and the second light-emitting elements of different colors. As shown in FIGS. 1 and 6 to 12, the display panel includes the multiple light-emitting element rows RO and the multiple light-emitting element columns CO; multiple light-emitting elements in the same light-emitting element row RO are arranged along the first direction X2, and the multiple light-emitting element rows RO are arranged along the second direction X3; and multiple light-emitting elements in the same light-emitting element column CO are arranged along the second direction X3, and the multiple light-emitting element columns CO are arranged along the first direction X2. In two adjacent light-emitting element rows RO along the second direction X3, light-emitting elements of different colors have different arrangements. For example, the i-th light-emitting element row ROᵢ includes the light-emitting elements of the first color 2R and the light-emitting elements of the third color 2G which are alternately arranged along the first direction X2, and the (i+1)-th light-emitting element row ROᵢ₊₁ includes the light-emitting elements of the second color 2B and the light-emitting elements of the third color 2G which are alternately arranged along the first direction X2. Moreover, in two adjacent light-emitting element columns CO along the first direction X2, light-emitting elements of different colors have different arrangements. For example, the j-th light-emitting element column COⱼ includes the light-emitting elements of the first color 2R and the light-emitting elements of the third color 2G which are alternately arranged along the second direction X3, and the (j+1)-th light-emitting element column COⱼ₊₁ includes the light-emitting elements of the second color 2B and the light-emitting elements of the third color 2G which are alternately arranged along the second direction X3. In this manner, the light-emitting elements of the first color 2R, the light-emitting elements of the second color 2B, and the light-emitting elements of the third color 2G can be uniformly and regularly arranged in both the first direction X2 and the second direction X3. Moreover, the light-emitting element of the first color 2R, the light-emitting element of the second color 2B, and the light-emitting element of the third color 2G are each one of the red light-emitting element, the blue light-emitting element, and the green light-emitting element and are different from each other so that the light-emitting elements of different colors can be uniformly and regularly arranged in the first direction X2 and the second direction X3, ensuring that the light-emitting elements of different colors have a better display rendering effect and further ensuring the color display effect of the display panel. Meanwhile, a distribution density of the light-emitting elements of the third color 2G is greater than a distribution density of the light-emitting elements of the first color 2R and a distribution density of the light-emitting elements of the second color 2B, and the light-emitting elements of the third color 2G may be green light-emitting elements. Such a setting conforms to the physiological characteristic that human eyes are most sensitive to green light, ensuring that a display effect of higher visual clarity can be achieved with lower power consumption.

It is to be noted that the light-emitting element row and the light-emitting element column in the embodiments of the present application may each be understood as a light-emitting element set formed by multiple light-emitting elements arranged along a particular direction. For example, a light-emitting element set formed by multiple light-emitting elements arranged along the first direction X2 may be a light-emitting element row, and a light-emitting element set formed by multiple light-emitting elements arranged along the second direction X3 may be a light-emitting element column. In the subsequent embodiments, a light-emitting element set formed by multiple light-emitting elements arranged along a third direction (the direction X4 shown in the figure, where the third direction X4 is used hereinafter as an example for description) may also be a light-emitting element row, and a light-emitting element set formed by multiple light-emitting elements arranged along a fourth direction (the direction X5 shown in the figure, where the fourth direction X5 is used hereinafter as an example for description) may also be a light-emitting element column. An arrangement direction of multiple light-emitting elements in the light-emitting element row is not unique, and an arrangement direction of multiple light-emitting elements in the light-emitting element column is not unique.

With continued reference to FIGS. 1 and 6 to 12, the display panel further includes multiple light-emitting element columns CO arranged along the third direction X4 and multiple light-emitting element rows RO arranged along the fourth direction X5, where the third direction X4 intersects the first direction X2, the second direction X3, and the fourth direction X5, and the fourth direction X5 intersects the first direction X2 and the second direction X3. A p-th light-emitting element row ROₚ includes light-emitting elements of the first color 2R and light-emitting elements of the second color 2B which are alternately arranged along the third direction X4; a (p+1)-th light-emitting element row ROₚ₊₁ includes multiple light-emitting elements of the third color 2G which are arranged along the third direction X4; a q-th light-emitting element column CO_{q} includes light-emitting elements of the first color 2R and light-emitting elements of the second color 2B which are alternately arranged along the fourth direction X5; and a (q+1)-th light-emitting element column CO_{q+1} includes multiple light-emitting elements of the third color 2G which are arranged along the fourth direction X5; where p and q are each a positive integer.

FIGS. 1 and 6 to 12 show multiple arrangements of the first light-emitting elements and the second light-emitting elements of different colors. As shown in FIGS. 1 and 6 to 12, the display panel includes the multiple light-emitting element rows RO and the multiple light-emitting element columns CO; multiple light-emitting elements in the same light-emitting element row RO are arranged along the third direction X4, and the multiple light-emitting element rows RO are arranged along the fourth direction X5; and multiple light-emitting elements in the same light-emitting element column CO are arranged along the fourth direction X5, and the multiple light-emitting element columns CO are arranged along the third direction X4. In two adjacent light-emitting element rows RO along the fourth direction X5, light-emitting elements of different colors have different arrangements. For example, the p-th light-emitting element row ROₚ includes the light-emitting elements of the first color 2R and the light-emitting elements of the second color 2B which are alternately arranged along the third direction X4, and the (p+1)-th light-emitting element row ROₚ₊₁ includes the multiple light-emitting elements of the third color (the same color) 2G which are arranged along the third direction X4. Moreover, in two adjacent light-emitting element columns CO along the third direction X4, light-emitting elements of different colors have different arrangements. For example, the q-th light-emitting element column CO_{q} includes the light-emitting elements of the first color 2R and the light-emitting elements of the second color 2B which are alternately arranged along the fourth direction X5, and the (q+1)-th light-emitting element column CO_{q+1} includes the multiple light-emitting elements of the third color (the same color) 2G which are arranged along the fourth direction X5. In this manner, the light-emitting elements of the first color 2R, the light-emitting elements of the second color 2B, and the light-emitting elements of the third color 2G can be uniformly and regularly arranged in both the third direction X4 and the fourth direction X5. Moreover, the light-emitting element of the first color 2R, the light-emitting element of the second color 2B, and the light-emitting element of the third color 2G are each one of the red light-emitting element, the blue light-emitting element, and the green light-emitting element and are different from each other so that the light-emitting elements of different colors can be uniformly and regularly arranged in the third direction X4 and the fourth direction X5, ensuring that the light-emitting elements of different colors have a better display rendering effect and further ensuring the color display effect of the display panel. Meanwhile, the distribution density of the light-emitting elements of the third color 2G is greater than the distribution density of the light-emitting elements of the first color 2R and the distribution density of the light-emitting elements of the second color 2B, and the light-emitting elements of the third color 2G may be the green light-emitting elements. Such a setting conforms to the physiological characteristic that human eyes are most sensitive to green light, ensuring that the display effect of higher visual clarity can be achieved with lower power consumption.

In one or more embodiments, with continued reference to FIGS. 1 and 2, the display panel further includes pixel circuits 5 and signal lines 6 located on the side of the substrate; the signal lines 6 include scanning signal lines 61 and data signal lines 62, and a pixel circuit 5 is electrically connected to a scanning signal line 61, a data signal line 62, and the light-emitting element 2, separately; and the scanning signal lines 61 extend along the third direction X4, and the data signal lines 62 extend along the fourth direction X5.

As shown in FIGS. 1 and 2, the display panel further includes multiple pixel circuits 5 and multiple signal lines 6 located on the side of the substrate 1. A pixel circuit 5 may include a transistor and a capacitor. For example, the pixel circuit 5 may include at least two transistors and at least one capacitor. That is, the pixel circuit 5 may have a “2T1C” structure, a “6T2C” structure, a “7T1C” structure, or an “8T1C” structure, where “T” represents the transistor and “C” represents the capacitor. A specific structure of the pixel circuit 5 is not limited in the embodiments of the present application. The pixel circuit is represented merely by the transistor shown in FIG. 2. The signal lines 6 may include the scanning signal lines 61, the data signal lines 62, and power signal lines (not shown in the figure). The pixel circuit 5 is electrically connected to the scanning signal line 61, the data signal line 62, and a power signal line, separately and configured to, under the action of a scanning signal provided by the scanning signal line 61, convert a data signal provided by the data signal line 62 and a power signal provided by the power signal line into a drive current signal for driving the light-emitting element 2 to emit light, so as to drive the light-emitting element 2 to perform light emission for display.

Further, the scanning signal lines 61 extend along the third direction X4, and the data signal lines 62 extend along the fourth direction X5. That is, an extension direction of the scanning signal lines 61 is the same as the arrangement direction of the multiple light-emitting elements 2 in the p-th light-emitting element row ROₚ or the (p+1)-th light-emitting element row ROₚ₊₁, and an extension direction of the data signal lines 62 is the same as the arrangement direction of the multiple light-emitting elements 2 in the q-th light-emitting element column CO_{q} or the (q+1)-th light-emitting element column CO_{q+1}, ensuring that the arrangement directions of the light-emitting elements 2 are consistent with the extension directions of the signal lines 6 and that the light-emitting elements 2 and the signal lines 6 are arranged regularly. Moreover, the scanning signal line 61 may be disposed between two adjacent light-emitting element rows RO, and the data signal line 62 may be disposed between two adjacent light-emitting element columns CO so that an effect of the arrangement of the signal lines 6 on the arrangement of the light-emitting elements 2 can be reduced, for example, an effect on the surface flatness of anodes in the light-emitting elements 2 can be reduced, ensuring the overall light emission effect of the light-emitting elements 2.

It is to be noted that to illustrate the light-emitting elements in FIG. 1 clearly, one scanning signal line 61 and one data signal line 62 are illustratively shown in FIG. 1. It is to be understood that the display panel includes multiple scanning signal lines 61 and multiple data signal lines 62, the multiple scanning signal lines 61 are arranged along the fourth direction X5, and the multiple data signal lines 62 are arranged along the third direction X4, where the details are not repeated here.

Based on the preceding embodiments, with continued reference to FIGS. 1 and 6 to 12, the light-emitting elements of the first color 2R include first light-emitting elements of the first color 21R and second light-emitting elements of the first color 22R, the light-emitting elements of the second color 2B include first light-emitting elements of the second color 21B and second light-emitting elements of the second color 22B, and the light-emitting elements of the third color 2G include first light-emitting elements of the third color 21G and second light-emitting elements of the third color 22G; the first light-emitting elements 21 include the first light-emitting elements of the first color 21R, the first light-emitting elements of the second color 21B, and the first light-emitting elements of the third color 21G; the second light-emitting elements 22 include the second light-emitting elements of the first color 22R, the second light-emitting elements of the second color 22B, and the second light-emitting elements of the third color 22G; the display panel further includes the multiple light-emitting element columns CO arranged along the third direction X4 and the multiple light-emitting element rows RO arranged along the fourth direction X5, where the third direction X4 intersects the first direction X2, the second direction X3, and the fourth direction X5, and the fourth direction X5 intersects the first direction X2 and the second direction X3; and in the same light-emitting element row among the multiple light-emitting element rows RO arranged along the fourth direction X5, first light-emitting elements 21 and second light-emitting elements 22 of the same color are alternately arranged along the third direction X4.

As shown in FIGS. 1 and 6 to 12, in the embodiments of the present application, the first light-emitting elements 21 include the first light-emitting elements of the first color 21R, the first light-emitting elements of the second color 21B, and the first light-emitting elements of the third color 21G; and the second light-emitting elements 22 include the second light-emitting elements of the first color 22R, the second light-emitting elements of the second color 22B, and the second light-emitting elements of the third color 22G. That is, either the first light-emitting elements 21 or the second light-emitting elements 22 include multiple light-emitting elements of different colors. In this manner, the first light-emitting elements of the first color 21R, the first light-emitting elements of the second color 21B, the first light-emitting elements of the third color 21G, the second light-emitting elements of the first color 22R, the second light-emitting elements of the second color 22B, and the second light-emitting elements of the third color 22G all emit light in the sharing mode, achieving color display at the normal viewing angle and the large viewing angle in the sharing mode. In the privacy mode, the first light-emitting elements of the first color 21R, the first light-emitting elements of the second color 21B, the first light-emitting elements of the third color 21G, first light-emitting portions 22a in the second light-emitting elements of the first color 22R, first light-emitting portions 22a in the second light-emitting elements of the second color 22B, and first light-emitting portions 22a in the second light-emitting elements of the third color 22G emit light normally, achieving color display at the normal viewing angle in the privacy mode. Moreover, second light-emitting portions 22b in the second light-emitting elements of the first color 22R, second light-emitting portions 22b in the second light-emitting elements of the second color 22B, and second light-emitting portions 22b in the second light-emitting elements of the third color 22G emit no light so that light-emitting portions for light emission at the large viewing angle are missing in the privacy mode, and the display information of at least part of the light-emitting element groups is blurred or disordered at the large viewing angle in the privacy mode, achieving the confidentiality of display information of at least part of the light-emitting element groups at the large viewing angle, and implementing the anti-peeping function.

Moreover, in the same light-emitting element row RO, the first light-emitting elements 21 and the second light-emitting elements 22 of the same color are alternately arranged along the third direction X4. That is, first light-emitting elements of the first color 21R and second light-emitting elements of the first color 22R are alternately arranged in the third direction X4, and/or first light-emitting elements of the second color 21B and second light-emitting elements of the second color 22B are alternately arranged in the third direction X4, and/or first light-emitting elements of the third color 21G and second light-emitting elements of the third color 22G are alternately arranged in the third direction X4. In this manner, the first light-emitting elements 21 with light emission at the large viewing angle and the second light-emitting elements 22 without light emission at the large viewing angle are uniformly distributed in the third direction X4, ensuring that the display panel has good uniformity in luminescence brightness in the third direction X4, avoiding relatively high display brightness of a region where the first light-emitting elements 21 with light emission at the large viewing angle are concentrated and densely arranged in the third direction X4 and relatively low display brightness of a region where the second light-emitting elements 22 without light emission at the large viewing angle are concentrated and densely arranged in the third direction X4, that is, avoiding that the display region of the light-emitting display panel is non-uniform in brightness in the third direction X4, and ensuring good uniformity in the display brightness of the display panel.

Specifically, with continued reference to FIGS. 1 and 6 to 12, in the p-th light-emitting element row ROₚ, the first light-emitting elements of the first color 21R and the second light-emitting elements of the first color 22R are alternately arranged along the third direction X4, and the first light-emitting elements of the second color 21B and the second light-emitting elements of the second color 22B are alternately arranged along the third direction X4, where p is a positive integer; and in the (p+1)-th light-emitting element row ROₚ₊₁, the first light-emitting elements of the third color 21G and the second light-emitting elements of the third color 22G are alternately arranged along the third direction X4.

As shown in FIGS. 1 and 6 to 12, two adjacent light-emitting element rows RO in the fourth direction X5 include the p-th light-emitting element row ROₚ and the (p+1)-th light-emitting element row ROₚ₊₁, and in the p-th light-emitting element row ROₚ, the light-emitting elements of the first color 2R and the light-emitting elements of the second color 2B are alternately arranged along the third direction X4, the first light-emitting elements of the first color 21R and the second light-emitting elements of the first color 22R are alternately arranged along the third direction X4, and the first light-emitting elements of the second color 21B and the second light-emitting elements of the second color 22B are alternately arranged along the third direction X4, ensuring good uniformity in the luminescence brightness of the first color and the second color in the third direction X4. Moreover, in the (p+1)-th light-emitting element row ROₚ₊₁, the first light-emitting elements of the third color 21G and the second light-emitting elements of the third color 22G are alternately arranged along the third direction X4, ensuring good uniformity in the luminescence brightness of the third color in the third direction X4. This further ensures that in the entire display region, the luminescence brightness of the first color, the second color, and the third color can have good uniformity and ensures good mixing uniformity of different colors, ensuring good uniformity in the luminescence brightness of color display of the display panel.

In one or more embodiments, with continued reference to FIGS. 1 and 6 to 12, in the same light-emitting element column CO, a first group GR1 and a second group GR2 are alternately arranged along the fourth direction X5; and the first group GR1 includes two first light-emitting elements 21 of the same color, and the second group GR2 includes two second light-emitting elements 22 of the same color.

As shown in FIGS. 1 and 6 to 12, the same light-emitting element column CO includes multiple groups GR, and a group GR may be understood as a light-emitting element set formed by two light-emitting elements 2 of the same color which are arranged in the fourth direction X5. Moreover, two groups GR adjacent to each other in the fourth direction X5 include the first group GR1 and the second group GR2, light-emitting elements included in the first group GR1 and the second group GR2 emit light of the same color, the first group GR1 includes two first light-emitting elements 21, and the second group GR2 includes two second light-emitting elements 22. In this manner, in the same light-emitting element column CO formed by multiple light-emitting elements 2 arranged along the fourth direction X5, the first light-emitting elements 21 and the second light-emitting elements 22 of the same color are alternately arranged in pairs along the fourth direction X5. That is, the first group GR1 including two first light-emitting elements of the first color 21R and the second group GR2 including two second light-emitting elements of the first color 22R are alternately arranged in the fourth direction X5; and/or the first group GR1 including two first light-emitting elements of the second color 21B and the second group GR2 including two second light-emitting elements of the second color 22B are alternately arranged in the fourth direction X5; and/or the first group GR1 including two first light-emitting elements of the third color 21G and the second group GR2 including two second light-emitting elements of the third color 22G are alternately arranged in the fourth direction X5. In this manner, the first group GR1 including the first light-emitting elements 21 with light emission at the large viewing angle and the second group GR2 including the second light-emitting elements 22 without light emission at the large viewing angle are uniformly distributed in the fourth direction X5, ensuring that the display panel has good uniformity in luminescence brightness in the fourth direction X5, avoiding relatively high display brightness of a region where first groups GR1 including the first light-emitting elements 21 with light emission at the large viewing angle are concentrated and densely arranged in the fourth direction X5 and relatively low display brightness of a region where second groups GR2 including the second light-emitting elements 22 without light emission at the large viewing angle are concentrated and densely arranged in the fourth direction X5, that is, avoiding that the display region of the light-emitting display panel is non-uniform in brightness in the fourth direction X5, and ensuring good uniformity in the display brightness of the display panel.

Further, with continued reference to FIGS. 1 and 6 to 12, the first group GR1 includes a first subgroup GR11, a second subgroup GR12, and a third subgroup GR13, and the second group GR2 includes a fourth subgroup GR21, a fifth subgroup GR22, and a sixth subgroup GR23. In the q-th light-emitting element column CO_{q}, the first subgroup GR11 and the fourth subgroup GR21 are alternately arranged along the fourth direction X5; the first subgroup GR11 includes two first light-emitting elements of the first color 21R which are adjacent to each other along the fourth direction X5; and the fourth subgroup GR21 includes two second light-emitting elements of the first color 22R which are adjacent to each other along the fourth direction X5; and q is a positive integer; in the q-th light-emitting element column CO_{q}, the second subgroup GR12 and the fifth subgroup GR22 are alternately arranged along the fourth direction X5; the second subgroup GR12 includes two first light-emitting elements of the second color 21B which are adjacent to each other along the fourth direction X5; and the fifth subgroup GR22 includes two second light-emitting elements of the second color 22B which are adjacent to each other along the fourth direction X5; in the (q+1)-th light-emitting element column CO_{q+1}, the third subgroup GR13 and the sixth subgroup GR23 are alternately arranged along the fourth direction X5; the third subgroup GR13 includes two first light-emitting elements of the third color 21G which are adjacent to each other along the fourth direction X5; and the sixth subgroup GR23 includes two second light-emitting elements of the third color 22G which are adjacent to each other along the fourth direction X5.

As shown in FIGS. 1 and 6 to 12, two adjacent light-emitting element columns CO in the third direction X4 include the q-th light-emitting element column CO_{q} and the (q+1)-th light-emitting element column CO_{q+1}. In the q-th light-emitting element column CO_{q}, the light-emitting elements of the first color 2R and the light-emitting elements of the second color 2B are alternately arranged along the fourth direction X5, ensuring a good color mixing effect of the first color and the second color. Moreover, in the q-th light-emitting element column CO_{q}, the first subgroup GR11 including two first light-emitting elements of the first color 21R and the fourth subgroup GR21 including two second light-emitting elements of the first color 22R are alternately arranged along the fourth direction X5, ensuring good uniformity in the luminescence brightness of the first color in the fourth direction X5. Further, in the q-th light-emitting element column CO_{q}, the second subgroup GR12 including two first light-emitting elements of the second color 21B and the fifth subgroup GR22 including two second light-emitting elements of the second color 22B are alternately arranged along the fourth direction X5, ensuring good uniformity in the luminescence brightness of the second color in the fourth direction X5. Further, in the (q+1)-th light-emitting element column CO_{q+1}, the third subgroup GR13 including two first light-emitting elements of the third color 21G and the sixth subgroup GR23 including two second light-emitting elements of the third color 22G are alternately arranged along the fourth direction X5, ensuring good uniformity in the luminescence brightness of the third color in the fourth direction X5. This further ensures that in the entire display region, the luminescence brightness of the first color, the second color, and the third color can have good uniformity and ensures good mixing uniformity of different colors, ensuring good uniformity in the luminescence brightness of color display of the display panel.

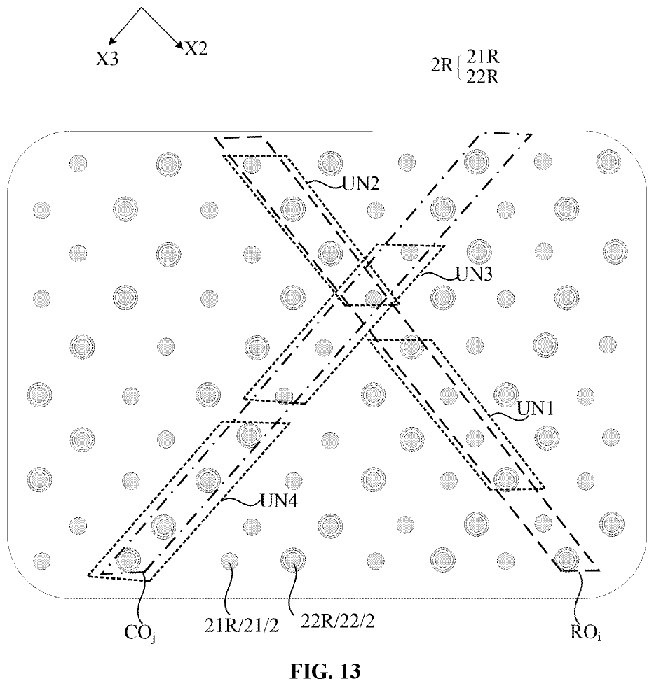

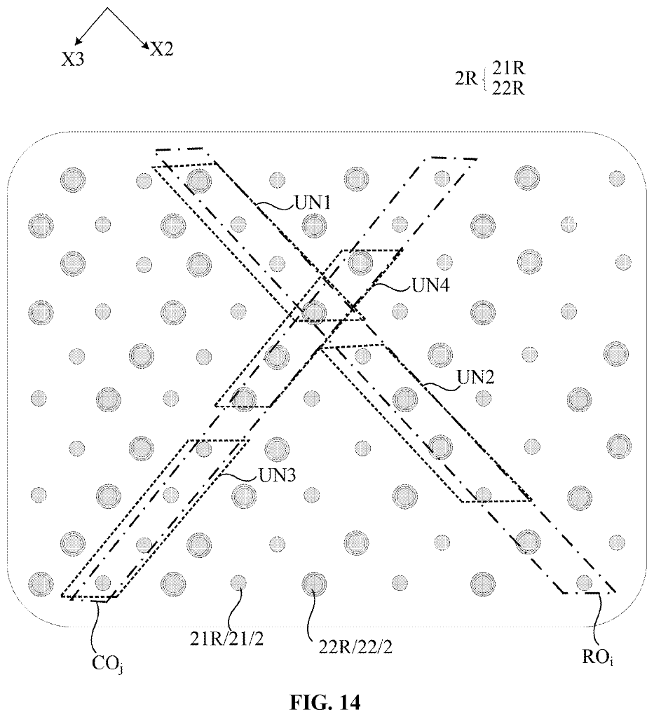

FIG. 13 is a schematic diagram of an arrangement of light-emitting elements of a first color according to embodiments of the present application. FIG. 14 is another schematic diagram of an arrangement of light-emitting elements of a first color according to embodiments of the present application. The arrangement of the light-emitting elements of the first color in FIG. 13 is the same as the arrangement of the light-emitting elements of the first color in FIGS. 1, 7, 9, and 11, and the arrangement of the light-emitting elements of the first color in FIG. 14 is the same as the arrangement of the light-emitting elements of the first color in FIGS. 6, 8, 10, and 12. As shown in FIGS. 13 and 14, the display panel according to the embodiments of the present application may further include a first light-emitting group UN1, a second light-emitting group UN2, a third light-emitting group UN3, and a fourth light-emitting group UN4; the first light-emitting group UN1 includes four light-emitting elements of the first color 2R which are adjacent to each other along the first direction X2, and along the first direction X2, two adjacent first light-emitting elements of the first color 21R are located between two adjacent second light-emitting elements of the first color 22R; the second light-emitting group UN2 includes four light-emitting elements of the first color 2R which are adjacent to each other along the first direction X2, and along the first direction X2, two adjacent second light-emitting elements of the first color 22R are located between two adjacent first light-emitting elements of the first color 21R; the third light-emitting group UN3 includes four first light-emitting elements of the first color 21R which are adjacent to each other along the second direction X3; the fourth light-emitting group UN4 includes four second light-emitting elements of the first color 22R which are adjacent to each other along the second direction X3; in the i-th light-emitting element row ROᵢ, the first light-emitting group UN1 and the second light-emitting group UN2 are alternately arranged along the first direction X2; and in the j-th light-emitting element column COⱼ, the third light-emitting group UN3 and the fourth light-emitting group UN4 are alternately arranged along the second direction X3.

As shown in FIGS. 13 and 14, the i-th light-emitting element row ROᵢ includes the first light-emitting group UN1 and the second light-emitting group UN2 alternately arranged in the first direction X2; the first light-emitting group UN1 includes four light-emitting elements of the first color 2R which are adjacent to each other along the first direction X2, and along the first direction X2, two adjacent first light-emitting elements of the first color 21R are located between two adjacent second light-emitting elements of the first color 22R; and the second light-emitting group UN2 includes four light-emitting elements of the first color 2R which are adjacent to each other along the first direction X2, and along the first direction X2, two adjacent second light-emitting elements of the first color 22R are located between two adjacent first light-emitting elements of the first color 21R. This can ensure that in the i-th light-emitting element row ROᵢ, the first light-emitting elements of the first color 21R and the second light-emitting elements of the first color 22R are uniformly and dispersedly arranged. That is, in the privacy mode, the first light-emitting elements of the first color 21R with light emitted at the large viewing angle and the second light-emitting elements of the first color 22R with no light emitted at the large viewing angle are uniformly and dispersedly arranged, ensuring good uniformity in the luminescence brightness of the first color in the first direction X2, avoiding relatively high display brightness of the first color in a region where the first light-emitting elements of the first color 21R with light emission at the large viewing angle are concentrated and densely arranged in the first direction X2 and relatively low display brightness of the first color in a region where the second light-emitting elements of the first color 22R without light emission at the large viewing angle are concentrated and densely arranged in the first direction X2, that is, avoiding that the display region of the light-emitting display panel is non-uniform in the brightness of the first color in the first direction X2, and ensuring good uniformity in the display brightness of the first color of the display panel. Further, the j-th light-emitting element column COⱼ includes the third light-emitting group UN3 and the fourth light-emitting group UN4, the third light-emitting group UN3 includes four first light-emitting elements of the first color 21R which are adjacent to each other along the second direction X3, and the fourth light-emitting group UN4 includes four second light-emitting elements of the first color 22R which are adjacent to each other along the second direction X3, ensuring that in the j-th light-emitting element column COⱼ, the first light-emitting elements of the first color 21R and the second light-emitting elements of the first color 22R are alternately arranged in groups of four, that is, the first light-emitting elements of the first color 21R and the second light-emitting elements of the first color 22R are uniformly and dispersedly arranged. That is, in the privacy mode, the first light-emitting elements of the first color 21R with light emitted at the large viewing angle and the second light-emitting elements of the first color 22R with no light emitted at the large viewing angle are uniformly and dispersedly arranged, ensuring good uniformity in the luminescence brightness of the first color in the second direction X3, avoiding relatively high display brightness of the first color in a region where the first light-emitting elements of the first color 21R with light emission at the large viewing angle are concentrated and densely arranged in the second direction X3 and relatively low display brightness of the first color in a region where the second light-emitting elements of the first color 22R without light emission at the large viewing angle are concentrated and densely arranged in the second direction X3, that is, avoiding that the display region of the light-emitting display panel is non-uniform in the brightness of the first color in the second direction X3, and ensuring good uniformity in the display brightness of the first color of the display panel.

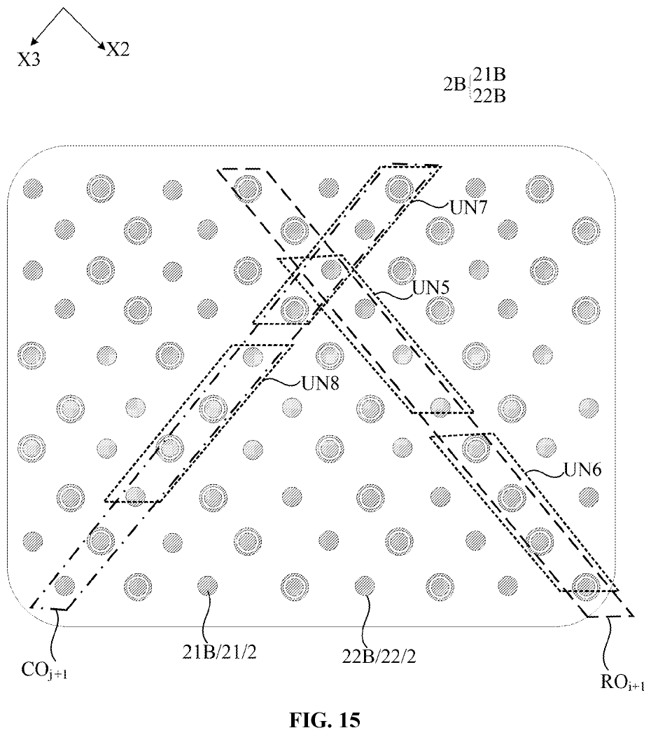

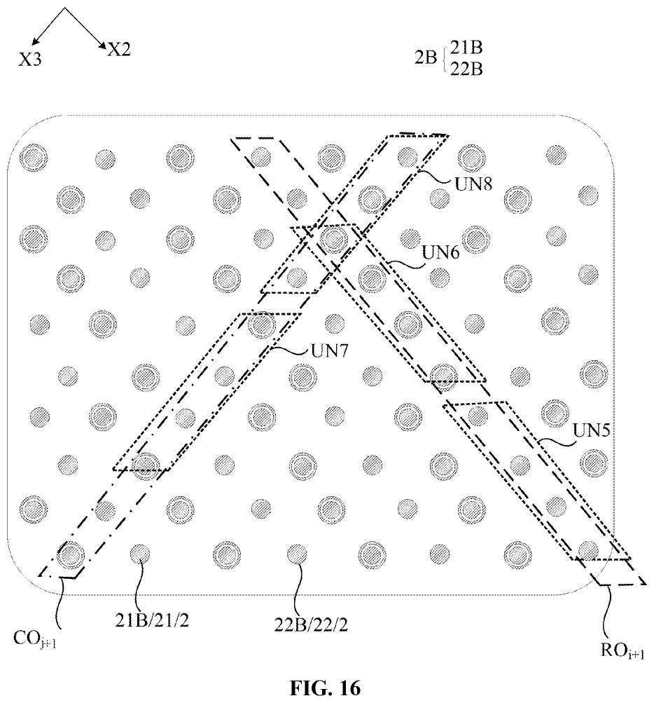

FIG. 15 is a schematic diagram of an arrangement of light-emitting elements of a second color according to embodiments of the present application. FIG. 16 is another schematic diagram of an arrangement of light-emitting elements of a second color according to embodiments of the present application. The arrangement of the light-emitting elements of the second color in FIG. 15 is the same as the arrangement of the light-emitting elements of the second color in FIGS. 1, 6, 9, and 10, and the arrangement of the light-emitting elements of the second color in FIG. 16 is the same as the arrangement of the light-emitting elements of the second color in FIGS. 7, 8, 11, and 12. As shown in FIGS. 15 and 16, the display panel according to the embodiments of the present application may further include a fifth light-emitting group UN5, a sixth light-emitting group UN6, a seventh light-emitting group UN7, and an eighth light-emitting group UN8; the fifth light-emitting group UN5 includes four first light-emitting elements of the second color 21B which are adjacent to each other along the first direction X2; the sixth light-emitting group UN6 includes four second light-emitting elements of the second color 22B which are adjacent to each other along the first direction X2; the seventh light-emitting group UN7 includes four light-emitting elements of the second color 2B which are adjacent to each other along the second direction X3, and along the second direction X3, two adjacent first light-emitting elements of the second color 21B are located between two adjacent second light-emitting elements of the second color 22B; the eighth light-emitting group UN8 includes four light-emitting elements of the second color 2B which are adjacent to each other along the second direction X3, and along the second direction X3, two adjacent second light-emitting elements of the second color 22B are located between two adjacent first light-emitting elements of the second color 21B; in the (i+1)-th light-emitting element row ROᵢ₊₁, the fifth light-emitting group UN5 and the sixth light-emitting group UN6 are alternately arranged along the first direction X2; and in the (j+1)-th light-emitting element column COⱼ₊₁, the seventh light-emitting group UN7 and the eighth light-emitting group UN8 are alternately arranged along the second direction X3.

As shown in FIGS. 15 and 16, the (i+1)-th light-emitting element row ROᵢ₊₁ includes the fifth light-emitting group UN5 and the sixth light-emitting group UN6 alternately arranged along the first direction X2, the fifth light-emitting group UN5 includes four first light-emitting elements of the second color 21B which are adjacent to each other along the first direction X2, and the sixth light-emitting group UN6 includes four second light-emitting elements of the second color 22B which are adjacent to each other along the first direction X2. This can ensure that in the (i+1)-th light-emitting element row ROᵢ₊₁, the first light-emitting elements of the second color 21B and the second light-emitting elements of the second color 22B are alternately arranged in groups of four, that is, the first light-emitting elements of the second color 21B and the second light-emitting elements of the second color 22B are uniformly and dispersedly arranged. That is, in the privacy mode, the first light-emitting elements of the second color 21B with light emitted at the large viewing angle and the second light-emitting elements of the second color 22B with no light emitted at the large viewing angle are uniformly and dispersedly arranged, ensuring good uniformity in the luminescence brightness of the second color in the first direction X2, avoiding relatively high display brightness of the second color in a region where the first light-emitting elements of the second color 21B with light emission at the large viewing angle are concentrated and densely arranged in the first direction X2 and relatively low display brightness of the second color in a region where the second light-emitting elements of the second color 22B without light emission at the large viewing angle are concentrated and densely arranged in the first direction X2, that is, avoiding that the display region of the light-emitting display panel is non-uniform in the brightness of the second color in the first direction X2, and ensuring good uniformity in the display brightness of the second color of the display panel. Further, the (j+1)-th light-emitting element column COⱼ₊₁ includes the seventh light-emitting group UN7 and the eighth light-emitting group UN8 alternately arranged along the second direction X3; the seventh light-emitting group UN7 includes four light-emitting elements of the second color 2B which are adjacent to each other along the second direction X3, and along the second direction X3, two adjacent first light-emitting elements of the second color 21B are located between two adjacent second light-emitting elements of the second color 22B; and the eighth light-emitting group UN8 includes four light-emitting elements of the second color 2B which are adjacent to each other along the second direction X3, and along the second direction X3, two adjacent second light-emitting elements of the second color 22B are located between two adjacent first light-emitting elements of the second color 21B. Thus, the first light-emitting elements of the second color 21B and the second light-emitting elements of the second color 22B are uniformly and dispersedly arranged. That is, in the privacy mode, the first light-emitting elements of the second color 21B with light emitted at the large viewing angle and the second light-emitting elements of the second color 22B with no light emitted at the large viewing angle are uniformly and dispersedly arranged, ensuring good uniformity in the luminescence brightness of the second color in the second direction X3, avoiding relatively high display brightness of the second color in a region where the first light-emitting elements of the second color 21B with light emission at the large viewing angle are concentrated and densely arranged in the second direction X3 and relatively low display brightness of the second color in a region where the second light-emitting elements of the second color 22B without light emission at the large viewing angle are concentrated and densely arranged in the second direction X3, that is, avoiding that the display region of the light-emitting display panel is non-uniform in the brightness of the second color in the second direction X3, and ensuring good uniformity in the display brightness of the second color of the display panel.

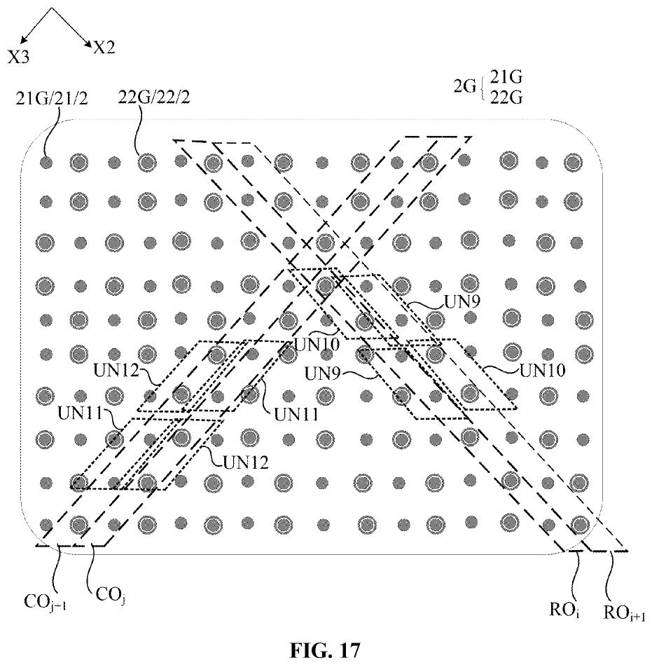

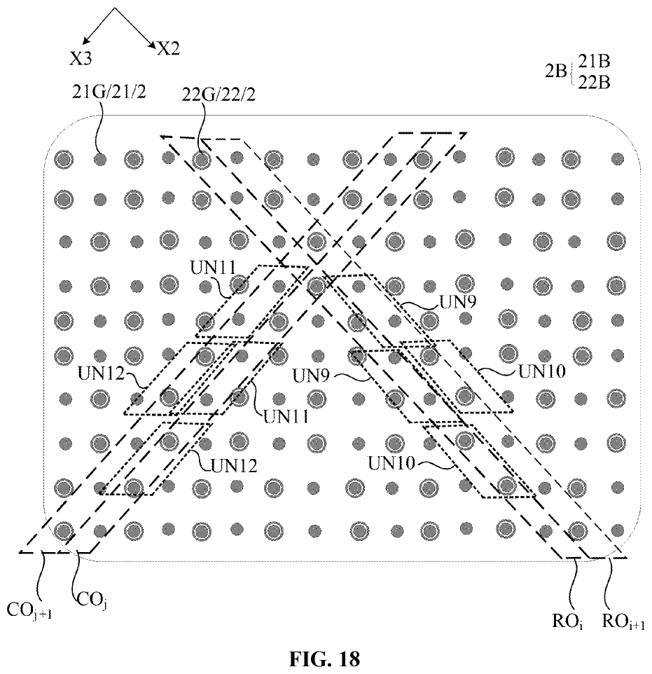

FIG. 17 is a schematic diagram of an arrangement of light-emitting elements of a third color according to embodiments of the present application. FIG. 18 is another schematic diagram of an arrangement of light-emitting elements of a third color according to embodiments of the present application. The arrangement of the light-emitting elements of the third color in FIG. 17 is the same as the arrangement of the light-emitting elements of the third color in FIGS. 1, 6, 7, and 8, and the arrangement of the light-emitting elements of the third color in FIG. 18 is the same as the arrangement of the light-emitting elements of the third color in FIGS. 9, 10, 11, and 12. As shown in FIGS. 17 and 18, the display panel according to the embodiments of the present application may further include a ninth light-emitting group UN9, a tenth light-emitting group UN10, an eleventh light-emitting group UN11, and a twelfth light-emitting group UN12; the ninth light-emitting group UN9 includes two first light-emitting elements of the third color 21G which are adjacent to each other along the first direction X2; the tenth light-emitting group UN10 includes two second light-emitting elements of the third color 22G which are adjacent to each other along the first direction X2; the eleventh light-emitting group UN11 includes two first light-emitting elements of the third color 21G which are adjacent to each other along the second direction X3; and the twelfth light-emitting group UN12 includes two second light-emitting elements of the third color 22G which are adjacent to each other along the second direction X3. In the i-th light-emitting element row ROᵢ, the ninth light-emitting group UN9 and the tenth light-emitting group UN10 are alternately arranged along the first direction X2; in the (i+1)-th light-emitting element row ROᵢ₊₁, the ninth light-emitting group UN9 and the tenth light-emitting group UN10 are alternately arranged along the first direction X2; in the j-th light-emitting element column COⱼ, the eleventh light-emitting group UN11 and the twelfth light-emitting group UN12 are alternately arranged along the second direction X3; and in the (j+1)-th light-emitting element column COⱼ₊₁, the eleventh light-emitting group UN11 and the twelfth light-emitting group UN12 are alternately arranged along the second direction X3.

As shown in FIGS. 17 and 18, each of the i-th light-emitting element row ROᵢ and the (i+1)-th light-emitting element row ROᵢ₊₁ includes the ninth light-emitting group UN9 and the tenth light-emitting group UN10 alternately arranged along the first direction X2, the ninth light-emitting group UN9 includes two first light-emitting elements of the third color 21G which are adjacent to each other along the first direction X2, and the tenth light-emitting group UN10 includes two second light-emitting elements of the third color 22G which are adjacent to each other along the first direction X2. This can ensure that in the i-th light-emitting element row ROᵢ and the (i+1)-th light-emitting element row ROᵢ₊₁, the first light-emitting elements of the third color 21G and the second light-emitting elements of the third color 22G are alternately arranged in pairs, that is, the first light-emitting elements of the third color 21G and the second light-emitting elements of the third color 22G are uniformly and dispersedly arranged. That is, in the privacy mode, the first light-emitting elements of the third color 21G with light emitted at the large viewing angle and the second light-emitting elements of the third color 22G with no light emitted at the large viewing angle are uniformly and dispersedly arranged, ensuring good uniformity in the luminescence brightness of the third color in the first direction X2, avoiding relatively high display brightness of the third color in a region where the first light-emitting elements of the third color 21G with light emission at the large viewing angle are concentrated and densely arranged in the first direction X2 and relatively low display brightness of the third color in a region where the second light-emitting elements of the third color 22G without light emission at the large viewing angle are concentrated and densely arranged in the first direction X2, that is, avoiding that the display region of the light-emitting display panel is non-uniform in the brightness of the third color in the first direction X2, and ensuring good uniformity in the display brightness of the third color of the display panel. Further, each of the j-th light-emitting element column COⱼ and the (j+1)-th light-emitting element column COⱼ₊₁ includes the eleventh light-emitting group UN11 and the twelfth light-emitting group UN12 alternately arranged along the second direction X3, the eleventh light-emitting group UN11 includes two first light-emitting elements of the third color 21G which are adjacent to each other along the second direction X3, and the twelfth light-emitting group UN12 includes two second light-emitting elements of the third color 22G which are adjacent to each other along the second direction X3. This can ensure that in the j-th light-emitting element column COⱼ and the (j+1)-th light-emitting element column COⱼ₊₁, the first light-emitting elements of the third color 21G and the second light-emitting elements of the third color 22G are alternately arranged in pairs, that is, the first light-emitting elements of the third color 21G and the second light-emitting elements of the third color 22G are uniformly and dispersedly arranged. That is, in the privacy mode, the first light-emitting elements of the third color 21G with light emitted at the large viewing angle and the second light-emitting elements of the third color 22G with no light emitted at the large viewing angle are uniformly and dispersedly arranged, ensuring good uniformity in the luminescence brightness of the third color in the second direction X3, avoiding relatively high display brightness of the third color in a region where the first light-emitting elements of the third color 21G with light emission at the large viewing angle are concentrated and densely arranged in the second direction X3 and relatively low display brightness of the third color in a region where the second light-emitting elements of the third color 22G without light emission at the large viewing angle are concentrated and densely arranged in the second direction X3, that is, avoiding that the display region of the light-emitting display panel is non-uniform in the brightness of the third color in the second direction X3, and ensuring good uniformity in the display brightness of the third color of the display panel.

To sum up, the arrangement of the first light-emitting elements and the second light-emitting elements of the same color and the arrangement of the light-emitting elements of different colors are reasonably set in the first direction, the second direction, the third direction, and the fourth direction, ensuring good display uniformity of the first color, the second color, and the third color in different directions.

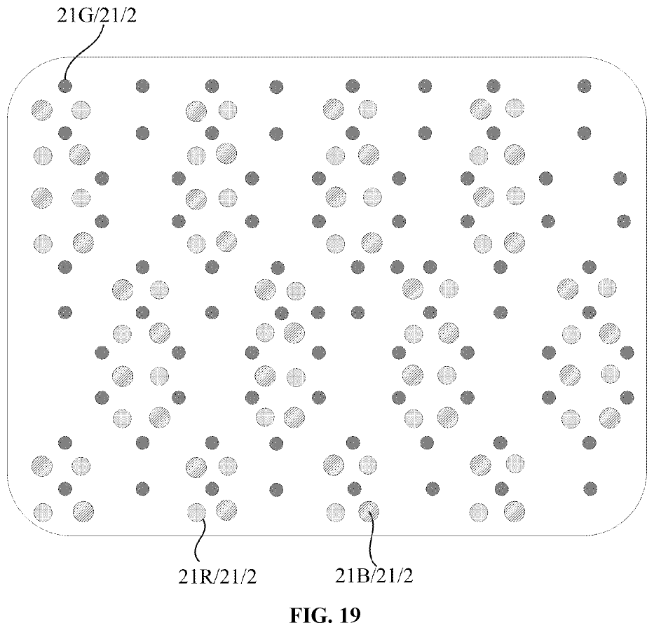

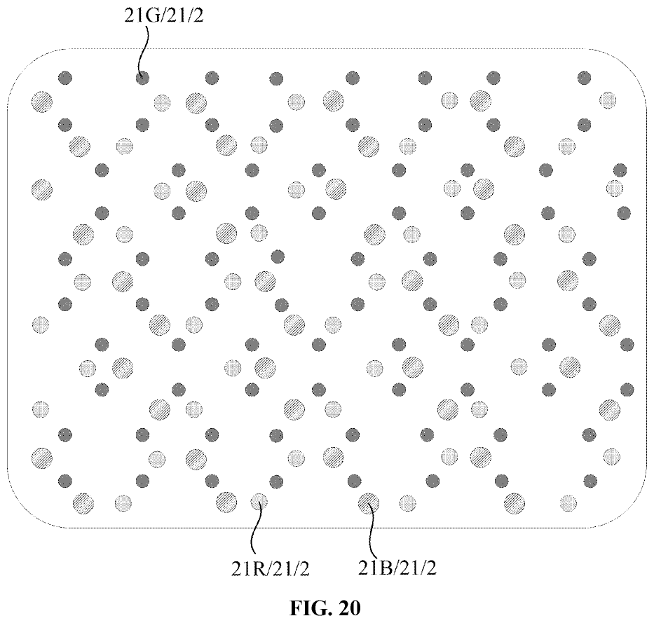

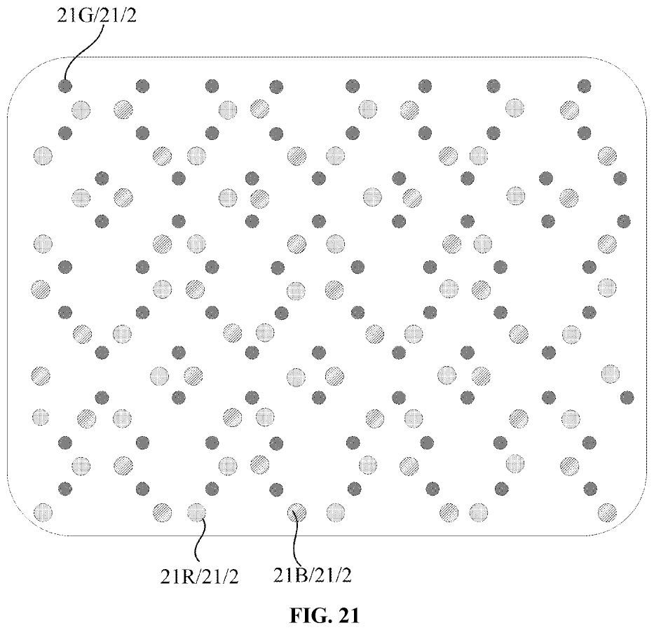

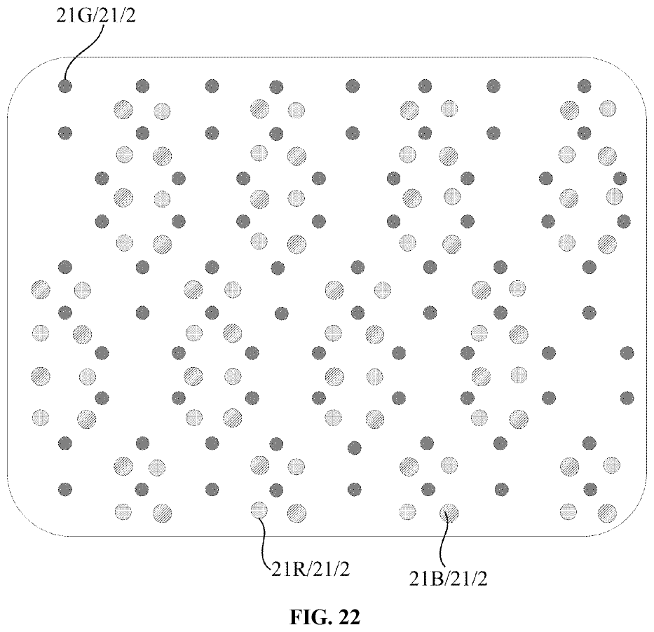

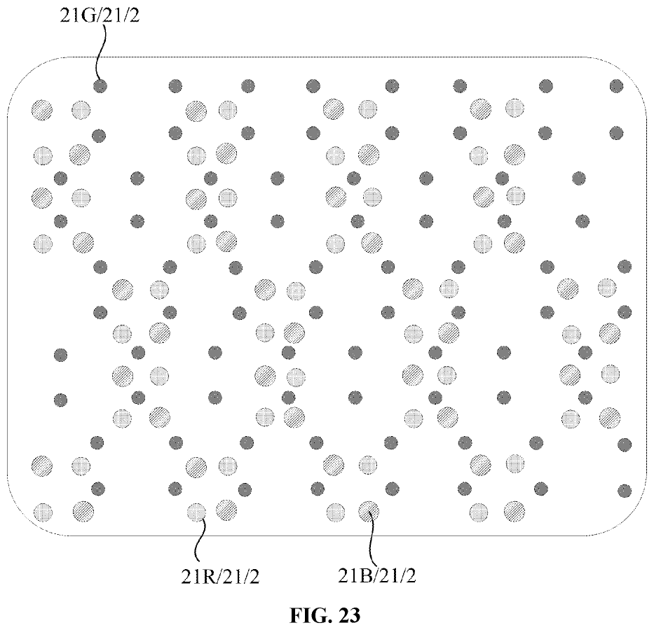

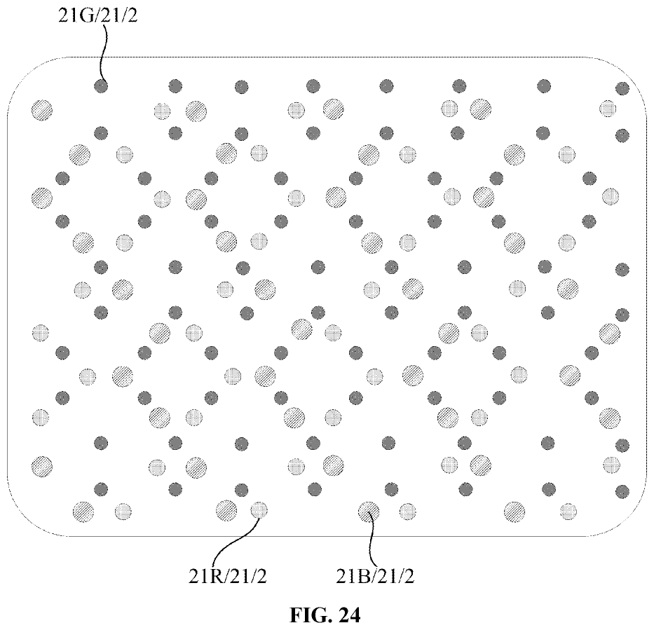

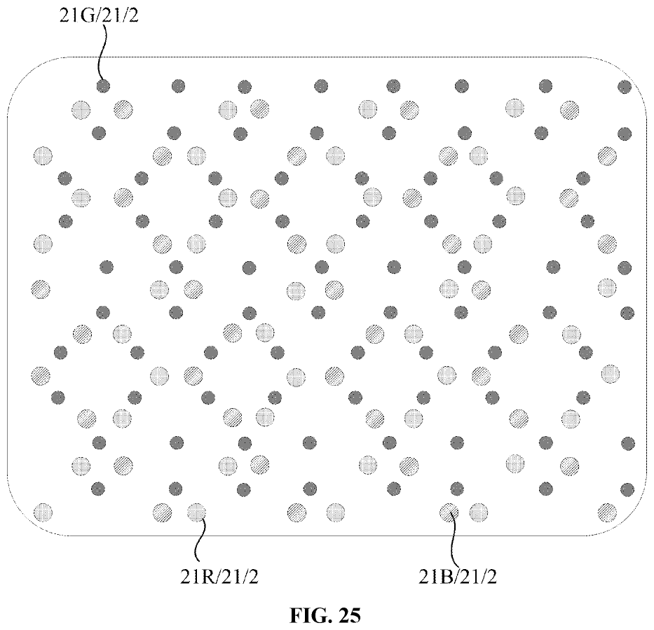

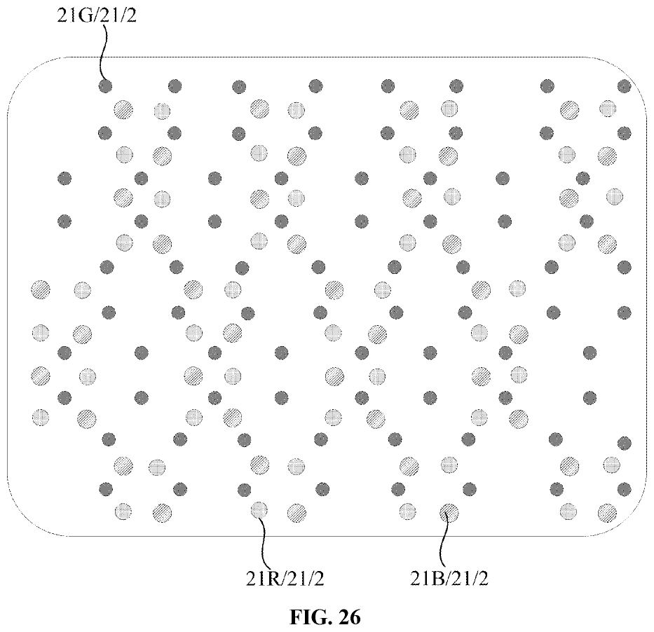

Further, FIG. 19 is a schematic diagram of an arrangement of light-emitting elements whose light emission is visible at a large viewing angle in a privacy mode of the display panel corresponding to FIG. 1, FIG. 20 is a schematic diagram of an arrangement of light-emitting elements whose light emission is visible at a large viewing angle in a privacy mode of the display panel corresponding to FIG. 6, FIG. 21 is a schematic diagram of an arrangement of light-emitting elements whose light emission is visible at a large viewing angle in a privacy mode of the display panel corresponding to FIG. 7, FIG. 22 is a schematic diagram of an arrangement of light-emitting elements whose light emission is visible at a large viewing angle in a privacy mode of the display panel corresponding to FIG. 8, FIG. 23 is a schematic diagram of an arrangement of light-emitting elements whose light emission is visible at a large viewing angle in a privacy mode of the display panel corresponding to FIG. 9, FIG. 24 is a schematic diagram of an arrangement of light-emitting elements whose light emission is visible at a large viewing angle in a privacy mode of the display panel corresponding to FIG. 10, FIG. 25 is a schematic diagram of an arrangement of light-emitting elements whose light emission is visible at a large viewing angle in a privacy mode of the display panel corresponding to FIG. 11, and FIG. 26 is a schematic diagram of an arrangement of light-emitting elements whose light emission is visible at a large viewing angle in a privacy mode of the display panel corresponding to FIG. 12. As shown in FIGS. 1 and 19, FIGS. 6 and 20, FIGS. 7 and 21, FIGS. 8 and 22, FIGS. 9 and 23, FIGS. 10 and 24, FIGS. 11 and 25, and FIGS. 12 and 26, the arrangement of the first light-emitting elements and the second light-emitting elements of the same color and the arrangement of the light-emitting elements of different colors are reasonably set in the first direction, the second direction, the third direction, and the fourth direction, ensuring that in the sharing mode, the first light-emitting element 21, the first light-emitting portion 22a, and the second light-emitting portion 22b all emit light so that the light emitted by the first light-emitting element 21 is visible at both the normal viewing angle and the large viewing angle, the light emitted by the first light-emitting portion 22a is visible at the normal viewing angle, and the light emitted by the second light-emitting portion 22b is visible at the large viewing angle. That is, the light emitted by the first light-emitting element 21 and the light emitted by the second light-emitting element 22 are visible at both the normal viewing angle and the large viewing angle, thereby achieving normal display at different viewing angles. At the large viewing angle in the privacy mode, as shown in FIGS. 19 to 26, although the first light-emitting portion 22a emits light, the light at the large viewing angle is invisible due to the shielding of the light-shielding structure, and the second light-emitting portion 22b does not emit light, so that the light emitted by the second light-emitting element 22 is invisible at the large viewing angle. Therefore, in the privacy mode with the large viewing angle, light emitted from the second light-emitting elements 22 (which is actually the light emitted by the first light-emitting portions 22a at this time) is invisible. This ensures that in the privacy mode, a color shift occurs due to partial light missing at the large viewing angle so that information displayed at the large viewing angle is blurred or disordered, achieving the confidentiality of display information at the large viewing angle.

Based on the preceding embodiments, with continued reference to FIGS. 1 to 12, the second light-emitting portion 22b surrounds the first light-emitting portion 22a. Thus, in the sharing mode, the second light-emitting portion 22b compensates for light of the first light-emitting portion 22a at the large viewing angle in all directions. That is, the second light-emitting portion 22b can compensate for the light of the first light-emitting portion 22a at the large viewing angle by 360°, thereby ensuring a visual effect of the second light-emitting element 22 at the large viewing angle and viewing-angle brightness at the large viewing angle in the sharing mode and ensuring a good display effect in the sharing mode.

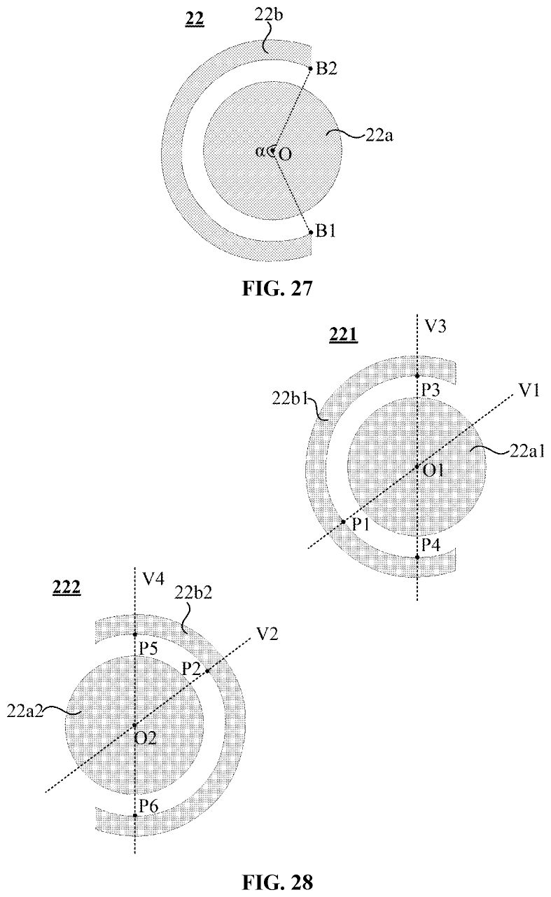

Based on the preceding embodiments, FIG. 27 is a structure diagram of a second light-emitting element according to embodiments of the present application. As shown in FIG. 27, the second light-emitting portion 22b surrounds part of the first light-emitting portion 22a; the second light-emitting portion 22b includes a first end B1 and a second end B2, a connection line between the first end B1 and the center O of the first light-emitting portion 22a is a first connection line B1O, and a connection line between the second end B2 and the center O of the first light-emitting portion 22a is a second connection line B2O; and a larger included angle α of two included angles formed by the first connection line B1O and the second connection line B2O satisfies that 180°≤α<360°.

As shown in FIG. 27, the second light-emitting portion 22b includes the first end B1 and the second end B2, the first end B1 may be any point in one edge region of the second light-emitting portion 22b, and the second end B2 may be any point in the other edge region of the second light-emitting portion 22b. Of the two angles formed by the first connection line B1O and the second connection line B2O, the larger angle α satisfies that 180°≤α<360°. That is, starting from B1, B2 can be reached through rotation by 180° to 360° in a clockwise direction. In other words, if an inner profile of the second light-emitting portion 22b is circular, an angle range of a central angle corresponding to arc B1B2 is 180° to 360°. As shown in FIG. 27, an azimuth angle corresponding to the first light-emitting portion 22a is 360°. That is, from any point on an edge of the first light-emitting portion 22a, the rotation by 360° in the clockwise or counterclockwise direction is required to return to the point. Of the two angles formed by the first connection line B1O and the second connection line B2O, the larger angle α satisfies that 180°≤α<360° so that although the second light-emitting portion 22b does not completely surround the first light-emitting portion 22a, the second light-emitting portion 22b surrounds at least half of the first light-emitting portion 22a, ensuring that the second light-emitting portion 22b can compensate for the light of the first light-emitting portion 22a at the large viewing angle within a relatively large azimuth angle. In other words, the second light-emitting portion 22b can compensate for the light of the first light-emitting portion 22a at the large viewing angle to a relatively large extent, thereby ensuring the visual effect of the second light-emitting element 22 at the large viewing angle and the viewing-angle brightness at the large viewing angle in the sharing mode to a relatively large extent and ensuring a good display effect in the sharing mode.

Further, FIG. 28 is a structure diagram of two adjacent second light-emitting elements emitting light of the same color according to embodiments of the present application. As shown in FIG. 28, two adjacent second light-emitting elements emitting light of the same color include a first second light-emitting element 221 and a second second light-emitting element 222; the first second light-emitting element 221 includes a first first light-emitting portion 22a1 and a first second light-emitting portion 22b1, and the first second light-emitting portion 22b1 surrounds part of the first first light-emitting portion 22a1; the second second light-emitting element 222 includes a second first light-emitting portion 22a2 and a second second light-emitting portion 22b2, and the second second light-emitting portion 22b2 surrounds part of the second first light-emitting portion 22a2. The display panel further includes a first virtual line V1 and a second virtual line V2 parallel to each other, the first virtual line V1 passes through the center O1 of the first first light-emitting portion 22a1 and intersects the first second light-emitting portion 22b1 only at a first intersection position P1, and the second virtual line V2 passes through the center O2 of the second first light-emitting portion 22a2 and intersects the second second light-emitting portion 22b2 only at a second intersection position P2; and a direction from the center O1 of the first first light-emitting portion 22a1 to the first intersection position P1 is opposite to a direction from the center O2 of the second first light-emitting portion 22a2 to the second intersection position P2.

As shown in FIG. 28, in the first second light-emitting element 221, the first second light-emitting portion 22b1 surrounds part of the first first light-emitting portion 22a1; and in the second second light-emitting element 222, the second second light-emitting portion 22b2 surrounds part of the second first light-emitting portion 22a2. Two parallel virtual lines may be found in the display panel, for example, the first virtual line V1 and the second virtual line V2. The first virtual line V1 passes through the center O1 of the first first light-emitting portion 22a1 and intersects the first second light-emitting portion 22b1 at only one intersection position P1, and the second virtual line V2 passes through the center O2 of the second first light-emitting portion 22a2 and intersects the second second light-emitting portion 22b2 at only one intersection position P2. Moreover, the direction from the center O1 of the first first light-emitting portion 22a1 to the first intersection position P1 is opposite to the direction from the center O2 of the second first light-emitting portion 22a2 to the second intersection position P2, which may be understood as that a relative position relationship between the first first light-emitting portion 22a1 and the first second light-emitting portion 22b1 is different from a relative position relationship between the second first light-emitting portion 22a2 and the second second light-emitting portion 22b2. For example, as shown in FIG. 28, the first second light-emitting portion 22b1 surrounds a left part of the first first light-emitting portion 22a1, and the second second light-emitting portion 22b2 surrounds a right part of the second first light-emitting portion 22a2. Alternatively, it may be understood as that an azimuth angle corresponding to the first second light-emitting portion 22b1 is different from an azimuth angle corresponding to the second second light-emitting portion 22b2. For example, as shown in FIG. 28, the azimuth angle corresponding to the first second light-emitting portion 22b1 has an azimuth angle range of 180° to 360°, and the azimuth angle corresponding to the second second light-emitting portion 22b2 has an azimuth angle range of 0° to 180°. In general, in the sharing mode, an azimuth angle within which the first second light-emitting portion 22b1 compensates for light of the first first light-emitting portion 22a1 at the large viewing angle is different from an azimuth angle within which the second second light-emitting portion 22b2 compensates for light of the second first light-emitting portion 22a2 at the large viewing angle.

Since the first second light-emitting element 221 and the second second light-emitting element 222 are two adjacent second light-emitting elements emitting light of the same color, the first second light-emitting portion 22b1 compensates for the light of the first first light-emitting portion 22a1 at the large viewing angle, and the second second light-emitting portion 22b2 compensates for the light of the second first light-emitting portion 22a2 at the large viewing angle so that an overall display effect exhibited when the first second light-emitting element 221 and the second second light-emitting element 222 jointly emit light can be light emission with the large viewing angle at different azimuth angles, ensuring the overall display effect and display brightness of the second light-emitting elements 22 at the large viewing angle in the sharing mode.

Further, with continued reference to FIG. 28, the display panel further includes a third virtual line V3 and a fourth virtual line V4 parallel to each other, the third virtual line V3 passes through the center O1 of the first first light-emitting portion 22a1 and intersects the first second light-emitting portion at two intersection positions, and the fourth virtual line V4 passes through the center of the second first light-emitting portion 22a2 and intersects the second second light-emitting portion 22b2 at two intersection positions.

With continued reference to FIG. 28, the third virtual line V3 exists in the display panel, an extension direction of the third virtual line V3 intersects an extension direction of the first virtual line V1, and the third virtual line V3 passes through the center O1 of the first first light-emitting portion 22a1 and intersects the first second light-emitting portion 22b1 at two intersection positions, for example, P3 and P4. That is, the first second light-emitting portion 22b1 surrounds at least half of the first first light-emitting portion 22a1. In other words, the minimum range of the azimuth angle corresponding to the first second light-emitting portion 22b1 is 180°.

The fourth virtual line V4 parallel to the third virtual line V3 also exists in the display panel, an extension direction of the fourth virtual line V4 intersects an extension direction of the second virtual line V2, and the fourth virtual line V4 passes through the center O2 of the second first light-emitting portion 22a2 and intersects the second second light-emitting portion 22b2 at two intersection positions, for example, P5 and P6. That is, the second second light-emitting portion 22b2 surrounds at least half of the second first light-emitting portion 22a2. In other words, the minimum range of the azimuth angle corresponding to the second second light-emitting portion 22b2 is 180°.

In this manner, a spliced structure formed by splicing the first second light-emitting portion 22b1 and the second second light-emitting portion 22b2 can form at least a complete ring-shaped structure which can completely surround the first light-emitting portion 22a. In other words, the spliced structure formed by splicing the first second light-emitting portion 22b1 and the second second light-emitting portion 22b2 corresponds to an azimuth angle of 360° and can surround the first light-emitting portion 22a by 360°.

Since the first second light-emitting element 221 and the second second light-emitting element 222 are two adjacent second light-emitting elements emitting light of the same color, the first second light-emitting portion 22b1 compensates for the light of the first first light-emitting portion 22a1 at the large viewing angle within an azimuth angle of at least 180°, and the second second light-emitting portion 22b2 compensates for the light of the second first light-emitting portion 22a2 at the large viewing angle within an azimuth angle of at least 180° so that the overall display effect exhibited when the first second light-emitting element 221 and the second second light-emitting element 222 jointly emit light can be light emission at the large viewing angle within the whole azimuth angle, that is, light emission at the large viewing angle within an azimuth angle of 360°, fully ensuring the overall display effect and display brightness of the second light-emitting elements 22 at the large viewing angle in the sharing mode.

Based on the preceding embodiments, with continued reference to FIG. 2, the display panel further includes the multiple pixel circuits 5 located on the side of the substrate 1, the multiple pixel circuits 5 include a first pixel circuit 51, a second pixel circuit 52, and a third pixel circuit 53, the first pixel circuit 51 is electrically connected to the first light-emitting element 21, the second pixel circuit 52 is electrically connected to the first light-emitting portion 22a, and the third pixel circuit 53 is electrically connected to the second light-emitting portion 22b; and the first pixel circuit 51, the second pixel circuit 52, and the third pixel circuit 53 are independently disposed.

As shown in FIGS. 1 and 2, the display panel further includes the multiple pixel circuits 5 and the multiple signal lines 6 located on the side of the substrate 1. The pixel circuit 5 may include the transistor and the capacitor. For example, the pixel circuit 5 may include at least two transistors and at least one capacitor. That is, the pixel circuit 5 may have the “2T1C” structure, the “6T2C” structure, the “7T1C” structure, or the “8T1C” structure, where “T” represents the transistor and “C” represents the capacitor. The specific structure of the pixel circuit 5 is not limited in the embodiments of the present application. The pixel circuit is represented merely by the transistor shown in FIG. 2. The signal lines 6 may include the scanning signal lines 61, the data signal lines 62, and the power signal lines (not shown in the figure). The pixel circuit 5 is electrically connected to the scanning signal line 61, the data signal line 62, and the power signal line, separately and configured to, under the action of the scanning signal provided by the scanning signal line 61, convert the data signal provided by the data signal line 62 and the power signal provided by the power signal line into the drive current signal for driving the light-emitting element 2 to emit light, so as to drive the light-emitting element 2 to perform light emission for display.

Further, the first light-emitting element 21, the first light-emitting portion 22a, and the second light-emitting portion 22b all emit light in the sharing mode, and the first light-emitting element 21 and the first light-emitting portion 22a emit light and the second light-emitting portion 22b does not emit light in the privacy mode. That is, light emission stages of different light-emitting elements or different light-emitting portions are different. Moreover, different light-emitting elements 2 or different light-emitting portions may have different luminescence brightness. Therefore, the first pixel circuit 51 electrically connected to the first light-emitting element 21, the second pixel circuit 52 electrically connected to the first light-emitting portion 22a, and the third pixel circuit 53 electrically connected to the second light-emitting portion 22b are independently disposed, and the light emission stages and luminescence brightness of the first light-emitting element 21, the first light-emitting portion 22a, and the second light-emitting portion 22b are independently controlled through the first pixel circuit 51, the second pixel circuit 52, and the third pixel circuit 53, ensuring that the light emission control logic of the first light-emitting element 21, the first light-emitting portion 22a, and the second light-emitting portion 22b is simple and efficient.

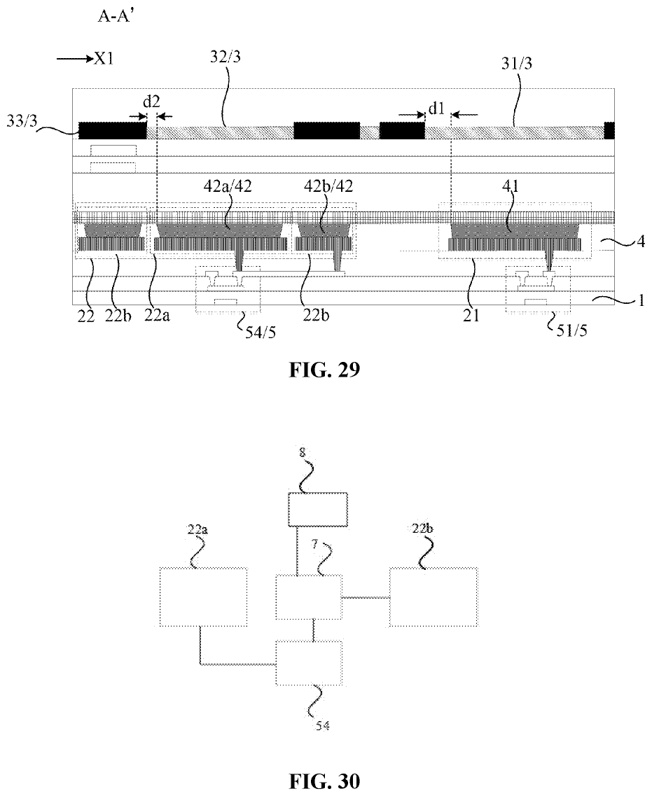

Based on the preceding embodiments, FIG. 29 is another sectional view of the display panel shown in FIG. 1 along line A-A′, and FIG. 30 is a schematic diagram of connections of a fourth pixel circuit with a first light-emitting portion and a second light-emitting portion according to embodiments of the present application. As shown in FIGS. 29 and 30, the display panel further includes the multiple pixel circuits 5 located on the side of the substrate 1; the multiple pixel circuits 5 include a first pixel circuit 51 and a fourth pixel circuit 54, the first pixel circuit 51 is electrically connected to the first light-emitting element 21, and the fourth pixel circuit 54 is electrically connected to the first light-emitting portion 22a and the second light-emitting portion 22b, separately; the display panel further includes a switch unit 7 and a control module 8, the switch unit 7 is connected in series between the fourth pixel circuit 54 and the second light-emitting portion 22b, and the control module 8 is electrically connected to the switch unit 7; the control module 8 is configured to control the switch unit 7 to be turned on in the sharing mode to conduct the fourth pixel circuit 54 with the second light-emitting portion 22b; and the control module 8 is further configured to control the switch unit 7 to be turned off in the privacy mode to disconnect the fourth pixel circuit 54 from the second light-emitting portion 22b.

Specifically, the pixel circuits 5 include the first pixel circuit 51 and the fourth pixel circuit 54, the first pixel circuit 51 is electrically connected to the first light-emitting element 21 and configured to control the first light-emitting element 21 to emit light, and the fourth pixel circuit 54 is electrically connected to the second light-emitting element 22 and configured to control the second light-emitting element 22 to emit light.

Further, since the second light-emitting portion 22b surrounds at least part of the first light-emitting portion 22a and configured to compensate for the light of the first light-emitting portion 22a at the large viewing angle, and the distance between the second light-emitting portion 22b and the first light-emitting portion 22a is relatively small, the second light-emitting portion 22b and the first light-emitting portion 22a may be configured to share the fourth pixel circuit 54, avoiding an additional pixel circuit 5 for the second light-emitting portion 22b and ensuring that an arrangement of the pixel circuits 5 in the display panel is simple. Moreover, in the privacy mode, the first light-emitting portion 22a emits light and the second light-emitting portion 22b does not emit light, that is, the light emission stages of the first light-emitting portion 22a and the second light-emitting portion 22b are different. Therefore, the switch unit 7 may be disposed between the fourth pixel circuit 54 and the second light-emitting portion 22b, and the switch unit 7 is controlled to be turned on or off to control the light emission of the first light-emitting portion 22a and the second light-emitting portion 22b.

Specifically, the fourth pixel circuit 54 is electrically connected to the first light-emitting portion 22a and electrically connected through the switch unit 7 to the second light-emitting portion 22b. In the sharing mode, the control module 8 controls the switch unit 7 to be turned on, and the fourth pixel circuit 54 controls the first light-emitting portion 22a and the second light-emitting portion 22b to emit light so that the second light-emitting element 22 performs normal light emission at the normal viewing angle and the large viewing angle. In the privacy mode, the control module 8 controls the switch unit 7 to be turned off, and the fourth pixel circuit 54 controls the first light-emitting portion 22a. In this case, the second light-emitting portion 22b does not emit light so that the second light-emitting element 22 performs normal light emission at the normal viewing angle and does not emit light at the large viewing angle, implementing the anti-peeping function.

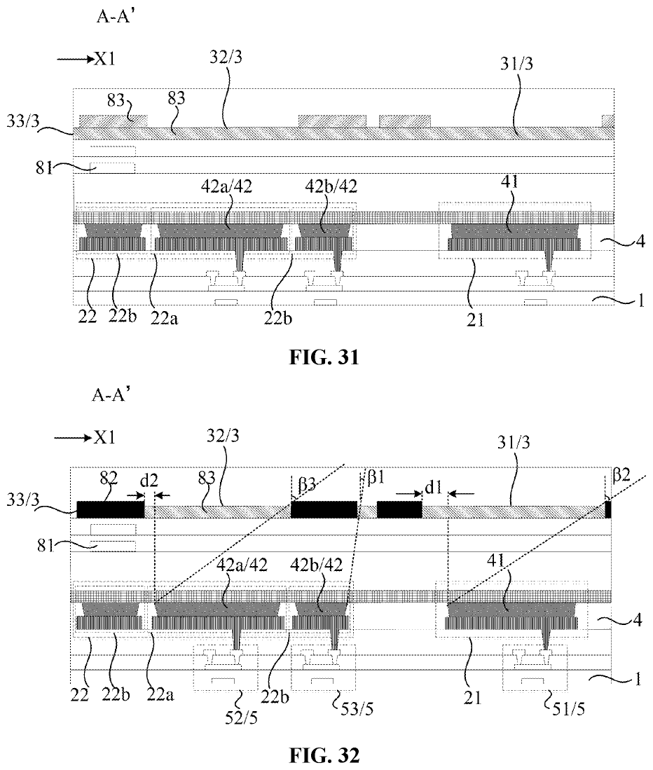

FIG. 31 is another sectional view of the display panel shown in FIG. 1 along line A-A′. As shown in FIGS. 2 and 31, the display panel further includes a touch structure 81, a color resist structure, and a black light-shielding layer 82 located on the side of the light-emitting elements 2 facing away from the substrate, and the color resist structure includes color resist layers 83 of different colors; and the light-shielding structure 3 includes at least one of the touch structure 81, at least two stacked color resist layers 83 of different colors, or the black light-shielding layer 82.

As shown in FIGS. 2 and 31, the display panel further includes the touch structure 81 located on the side of the light-emitting elements 2 facing away from the substrate. Users may perform touch operations on the display panel through the touch structure 81, improving an additional function of the display panel. Moreover, the touch structure 81 may include one or more touch function layers. FIGS. 2 and 31 illustrate that the touch structure 81 includes two touch function layers. The corresponding touch structure 81 may be a mutual-capacitance touch structure, and the mutual-capacitance touch structure can ensure that the touch operations of the touch structure 81 are sensitive and have relatively high precision.

Moreover, the display panel further includes the color resist structure located on the side of the light-emitting elements 2 facing away from the substrate. The color resist structure may include the color resist layers 83 of different colors. For example, the light-emitting elements of the first color may correspond to a color resist of the first color, which improves the color purity of the emitted light of the first color; the light-emitting elements of the second color may correspond to a color resist of the second color, which improves the color purity of the emitted light of the second color; and the light-emitting elements of the third color may correspond to a color resist of the third color, which improves the color purity of the emitted light of the third color. Additionally, the display panel includes the color resist structure, and the color resist structure can filter interference light from the external environment, reduce interference of the light from the external environment with the normal light emission of the display panel, and ensure the display effect of the display panel.

Furthermore, the display panel further includes the black light-shielding layer 82 located on the side of the light-emitting elements 2 facing away from the substrate. The black light-shielding layer 82 shields the signal lines in the display panel, such as the data signal lines or the scanning signal lines, to prevent the signal lines in the display panel from being visible. Additionally, the display panel includes the black light-shielding layer 82, and the black light-shielding layer 82 can filter the interference light from the external environment, reduce the interference of the light from the external environment with the normal light emission of the display panel, and ensure the display effect of the display panel.

Based on the preceding structure, the light-shielding structure 3 in the display panel may include at least one of the touch structure 81, at least two stacked color resist layers 83 of different colors, or the black light-shielding layer 82. FIG. 2 illustrates that the light-shielding structure 3 includes the black light-shielding layer 82. FIG. 31 illustrates that the light-shielding structure 3 includes at least two color resist layers 83 of different colors. The light-shielding structure 3 in the display panel may include at least one of the touch structure 81, at least two stacked color resist layers 83 of different colors, or the black light-shielding layer 82 so that a simple configuration of the light-shielding structure 3 can be ensured, an existing structure in the display panel can also serve as the light-shielding structure, and the thickness of films of the display panel is not increased, facilitating the thinning design of the display panel.

Based on the same inventive concept, embodiments of the present application provide a display panel. FIG. 32 is another sectional view of the display panel shown in FIG. 1 along line A-A′. As shown in FIGS. 1, 32, and 3 to 5, the display panel according to the embodiments of the present application includes a substrate 1 and multiple light-emitting elements 2 on a side of the substrate; the multiple light-emitting elements 2 include first light-emitting elements 21 and second light-emitting elements 22, a second light-emitting element 22 includes a first light-emitting portion 22a and a second light-emitting portion 22b, and the second light-emitting portion 22b surrounds at least part of the first light-emitting portion 22a. The maximum light-emitting viewing angle of the first light-emitting element 21 is greater than the maximum light-emitting viewing angle of the first light-emitting portion 22a, and the minimum light-emitting viewing angle of the second light-emitting portion 22b is greater than the minimum light-emitting viewing angle of the first light-emitting element 21 and the minimum light-emitting viewing angle of the first light-emitting portion 22a; display modes of the display panel include a sharing mode and a privacy mode; in the sharing mode, the first light-emitting element 21, the first light-emitting portion 22a, and the second light-emitting portion 22b all emit light; and in the privacy mode, the first light-emitting element 21 and the first light-emitting portion 22a emit light, and the second light-emitting portion 22b does not emit light.

As shown in FIGS. 1 and 32, the display panel includes the substrate 1 and the multiple light-emitting elements 2 on the side of the substrate 1. The light-emitting elements 2 may include light-emitting elements of different colors, for example, at least one of red light-emitting elements, green light-emitting elements, blue light-emitting elements, or white light-emitting elements. Moreover, the light-emitting element 2 may be one of an organic light-emitting diode, a micro organic light-emitting diode, or a micro light-emitting diode. In an example in which the light-emitting element 2 is the organic light-emitting diode, the light-emitting element 2 may include a first electrode, a second electrode, and an organic compound layer located between the first electrode and the second electrode. The organic compound layer may include, but is not limited to, a hole injection layer, a hole transport layer, an electron blocking layer, a light-emitting layer, an electron transport layer, a hole blocking layer, and an electron injection layer. Alternatively, the organic compound layer may also include a charge generation layer, such as a p-type charge generation layer or an n-type charge generation layer. When a voltage is applied between the first electrode and the second electrode of the organic light-emitting diode, holes transported through the hole transport layer and electrons transported through the electron transport layer move to the light-emitting layer to form excitons, resulting in emission of visible light from the light-emitting layer.

Further, with continued reference to FIG. 32, the display panel further includes a pixel defining layer 4, the pixel defining layer 4 is provided with multiple pixel openings, and each pixel opening is used for defining a light-emitting region of the light-emitting element. Specifically, the light-emitting elements 2 include the first light-emitting elements 21 and the second light-emitting elements 22, the second light-emitting element 22 includes the first light-emitting portion 22a and the second light-emitting portion 22b, and the second light-emitting portion 22b surrounds at least part of the first light-emitting portion 22a. Correspondingly, the pixel defining layer 4 includes a first pixel opening 41 and a second pixel opening 42, the second pixel opening 42 includes a first pixel opening portion 42a and a second pixel opening portion 42b, and the second pixel opening portion 42b surrounds at least part of the first pixel opening portion 42a. At least part of the first light-emitting element 21 is located within the first pixel opening 41. That is, at least part of a light-emitting film of the first light-emitting element 21 is located within the first pixel opening 41, and the first pixel opening 41 defines at least part of a light-emitting region of the first light-emitting element 21. At least part of the first light-emitting portion 22a is located within the first pixel opening portion 42a. That is, at least part of a light-emitting film of the first light-emitting portion 22a is located within the first pixel opening portion 42a, and the first pixel opening portion 42a defines at least part of a light-emitting region of the first light-emitting portion 22a. At least part of the second light-emitting portion 22b is located within the second pixel opening portion 42b. That is, at least part of a light-emitting film of the second light-emitting portion 22b is located within the second pixel opening portion 42b, and the second pixel opening portion 42b defines at least part of a light-emitting region of the second light-emitting portion 22b. The pixel defining layer 4 and the pixel openings are disposed, and the pixel opening defines at least part of the light-emitting film of the light-emitting element so that crosstalk between different light-emitting elements can be reduced, and a light emission contrast between different light-emitting elements can be improved.

Further, with continued reference to FIG. 32, the display panel further includes a light-shielding structure 3 located on a light emission side of the light-emitting elements, and the light-shielding structure 3 is used for adjusting light-emitting viewing angles of the light-emitting elements 2. Specifically, the light-shielding structure 3 includes a first opening 31, a second opening 32, and a first light-shielding portion 33, and along a direction perpendicular to a plane where the substrate 1 is located (the direction Y shown in the figure), the first opening 31 at least partially overlaps the first light-emitting element 21 so that at least part of light from the first light-emitting element 21 can be emitted through the first opening 31, and the second opening 32 at least partially overlaps the first light-emitting portion 22a so that at least part of light from the first light-emitting portion 22a can be emitted through the second opening 32. In other words, at least light emitted by the first light-emitting element 21 at a normal viewing angle or small viewing angle can be emitted through the first opening 31, and light emitted by the first light-emitting portion 22a at the normal viewing angle or small viewing angle can be emitted through the second opening 32. The first light-shielding portion 33 at least partially overlaps the second light-emitting portion 22b so that at least part of light emitted by the second light-emitting portion 22b at the normal viewing angle or small viewing angle is shielded by the first light-shielding portion 33 and cannot be emitted, and at least part of light emitted by the second light-emitting portion 22b at a large viewing angle can be emitted through the second opening 32. That is, the minimum light-emitting viewing angle of the second light-emitting portion 22b is greater than the minimum light-emitting viewing angle of the first light-emitting element 21 and the first light-emitting portion 22a. As shown in FIG. 32, the minimum light-emitting viewing angle β1 of the second light-emitting portion 22b is greater than 0°, and the minimum light-emitting viewing angle of the first light-emitting element 21 and the minimum light-emitting viewing angle of the first light-emitting portion 22a are equal to 0°. Moreover, along a direction parallel to the plane where the substrate 1 is located (the direction X1 shown in the figure), the minimum distance d1 between an edge of the first opening 31 and an edge of the first pixel opening 41 and the minimum distance d2 between an edge of the second opening 32 and an edge of the first pixel opening portion 42a satisfy that d1>d2. That is, the distance between the edge of the first opening 31 and the edge of the first pixel opening 41 is larger, and the distance between the edge of the second opening 32 and the edge of the first pixel opening portion 42a is smaller so that light emitted by the first light-emitting element 21 at a relatively large viewing angle can be emitted through the first opening 31 without being shielded by a light-shielding region outside the first opening 31, while light emitted by the first light-emitting portion 22a at a relatively large viewing angle is shielded by a light-shielding region outside the second opening 32 and cannot be emitted through the second opening 32. That is, through the light-shielding structure 3, the maximum light-emitting viewing angle of the first light-emitting element 21 is greater than the maximum light-emitting viewing angle of the first light-emitting portion 22a. As shown in FIG. 32, the maximum light-emitting viewing angle β2 of the first light-emitting element 21 is greater than the maximum light-emitting viewing angle β3 of the first light-emitting portion 22a.

It is to be understood that the viewing angle in the embodiments of the present application may be understood as an acute angle formed between a propagation direction of light emitted by the light-emitting element and a thickness direction of the display panel. The light emitted at the normal viewing angle or small viewing angle may be understood as that the angle between the direction of the light emitted by the light-emitting element and the thickness direction of the display panel is relatively small, for example, 0°, 5°, or 10°, or the formed acute angle is less than 30°. The light emitted at the large viewing angle may be understood as that the angle between the direction of the light emitted by the light-emitting element and the thickness direction of the display panel is relatively large, for example, 50°, 60°, or 70°, or the formed acute angle is greater than or equal to 45°. In the embodiments of the present application, the small viewing angle and the large viewing angle are relative concepts. The magnitude of the small viewing angle or the large viewing angle is not numerically limited in the embodiments of the present application.

Specifically, the display modes of the display panel include the sharing mode and the privacy mode. In the sharing mode, the first light-emitting element 21, the first light-emitting portion 22a, and the second light-emitting portion 22b all emit light so that the light emitted by the first light-emitting element 21 is visible at both the normal viewing angle and the large viewing angle, the light emitted by the first light-emitting portion 22a is visible at the normal viewing angle, and the light emitted by the second light-emitting portion 22b is visible at the large viewing angle. That is, the light emitted by the first light-emitting element 21 and the light emitted by the second light-emitting element 22 are visible at both the normal viewing angle and the large viewing angle, thereby achieving normal display at different viewing angles. In the privacy mode, the first light-emitting element 21 and the first light-emitting portion 22a emit light, and the second light-emitting portion 22b does not emit light so that the light emitted by the first light-emitting element 21 is visible at both the normal viewing angle and the large viewing angle, and the light emitted by the first light-emitting portion 22a is visible at the normal viewing angle, ensuring that the display panel has normal display content and display brightness and achieves normal display at the normal viewing angle. No light emitted by the second light-emitting portion 22b is visible at the large viewing angle, that is, the light emitted by the second light-emitting element 22 is partially missing at the large viewing angle, resulting in a color shift due to partial light missing at the large viewing angle. Thus, information displayed at the large viewing angle is blurred or disordered, achieving the confidentiality of display information. It is to be understood that anti-peeping is to prevent information from being observed at the large viewing angle and prevent information from being peeped or seen at the large viewing angle, thereby achieving visibility within a narrow viewing angle and invisibility at the large viewing angle.

Further, the display panel includes multiple light-emitting element groups 20, and a light-emitting element group 20 includes at least one first light-emitting element 21 and at least one second light-emitting element 22. In this manner, the light emitted by the first light-emitting element 21 and the light emitted by the second light-emitting element 22 in the same light-emitting element group 20 are visible at both the normal viewing angle and the large viewing angle in the sharing mode, achieving normal display in the sharing mode. In the privacy mode, the same light-emitting element group 20 includes at least one second light-emitting portion 22b emitting no light. The second light-emitting portion 22b emitting no light can ensure that the light-emitting element group 20 and another light-emitting element group that also uses the second light-emitting portion 22b in this light-emitting element group both have the missing second light-emitting portion 22b, ensuring that at least part of the light-emitting element groups suffer display color shifts at the large viewing angle due to the missing second light-emitting portion 22b, ensuring that display information of at least part of the light-emitting element groups 20 is blurred or disordered at the large viewing angle, achieving the confidentiality of display information of at least part of the light-emitting element groups at the large viewing angle, achieving the confidentiality of display information of the entire display panel, and implementing the anti-peeping function.

Further, as shown in FIGS. 3 to 5, the light-emitting element group 20 may include one light-emitting element of a first color 2R, one light-emitting element of a second color 2B, and two light-emitting elements of a third color 2G. That is, the light-emitting element group 20 may have an RGBG structure. In this manner, in the same light-emitting element group 20 among at least part of the light-emitting element groups 20, one to three second light-emitting portions 22b emitting no light are present. The second light-emitting portions 22b emitting no light can ensure that the light-emitting element group 20 and another light-emitting element group that also uses the second light-emitting portions 22b in this light-emitting element group both have the missing second light-emitting portions 22b, thereby achieving the confidentiality of display information of at least part of the light-emitting element groups at the large viewing angle, achieving the confidentiality of display information of the entire display panel, and implementing the anti-peeping function. Moreover, as shown in FIGS. 3 to 5, the light-emitting element of the first color 2R, the light-emitting element of the second color 2B, and the light-emitting elements of the third color 2G in the same light-emitting element group 20 may be arranged in different manners, which are not limited in the embodiments of the present application.

To sum up, the display panel according to the embodiments of the present application includes the first light-emitting element, the first light-emitting portion, and the second light-emitting portion, the maximum light-emitting viewing angle of the first light-emitting element is greater than the maximum light-emitting viewing angle of the first light-emitting portion, and the minimum light-emitting viewing angle of the second light-emitting portion is greater than the minimum light-emitting viewing angle of the first light-emitting element and the first light-emitting portion, achieving normal light emission of the first light-emitting element at both the normal viewing angle and the large viewing angle, normal light emission of the first light-emitting portion at the normal viewing angle, and normal light emission of the second light-emitting portion at the large viewing angle. Further, light emission timings of the light-emitting elements and the light-emitting portions in different display modes are set so that the display panel performs normal display at different viewing angles in the sharing mode, and part of display content is missing at the large viewing angle in the privacy mode, implementing the anti-peeping function. Moreover, each light-emitting element group includes at least one first light-emitting element and at least one second light-emitting element, ensuring that each light-emitting element group can achieve normal display in the sharing mode, and the display information of at least part of the light-emitting element groups is blurred or disordered at the large viewing angle in the privacy mode, achieving the confidentiality of display information of at least part of the light-emitting element groups at the large viewing angle, achieving the confidentiality of display information of the entire display panel, and implementing the anti-peeping function.

Based on the preceding embodiments, with continued reference to FIGS. 1 and 6 to 12, the display panel further includes light-emitting elements of the first color 2R, light-emitting elements of the second color 2B, and light-emitting elements of the third color 2G; a light-emitting element of the first color 2R, a light-emitting element of the second color 2B, and a light-emitting element of the third color 2G are each one of a red light-emitting element, a blue light-emitting element, and a green light-emitting element and are different from each other; the display panel further includes multiple light-emitting element columns CO arranged along a first direction (the direction X2 shown in the figure, where the first direction X2 is used hereinafter as an example for description) and multiple light-emitting element rows RO arranged along a second direction (the direction X3 shown in the figures, where the second direction X3 is used hereinafter as an example for description), and the first direction X2 intersects the second direction X3. An i-th light-emitting element row ROᵢ includes light-emitting elements of the first color 2R and light-emitting elements of the third color 2G which are alternately arranged along the first direction X2; an (i+1)-th light-emitting element row ROᵢ₊₁ includes light-emitting elements of the second color 2B and light-emitting elements of the third color 2G which are alternately arranged along the first direction X2; a j-th light-emitting element column COⱼ includes light-emitting elements of the first color 2R and light-emitting elements of the third color 2G which are alternately arranged along the second direction X3; and a (j+1)-th light-emitting element column COⱼ₊₁ includes light-emitting elements of the second color 2B and light-emitting elements of the third color 2G which are alternately arranged along the second direction X3, where i and j are each a positive integer.

FIGS. 1 and 6 to 12 show multiple arrangements of first light-emitting elements and second light-emitting elements of different colors. As shown in FIGS. 1 and 6 to 12, the display panel includes the multiple light-emitting element rows RO and the multiple light-emitting element columns CO; multiple light-emitting elements in the same light-emitting element row RO are arranged along the first direction X2, and the multiple light-emitting element rows RO are arranged along the second direction X3; and multiple light-emitting elements in the same light-emitting element column CO are arranged along the second direction X3, and the multiple light-emitting element columns CO are arranged along the first direction X2. In two adjacent light-emitting element rows RO along the second direction X3, light-emitting elements of different colors have different arrangements. For example, the i-th light-emitting element row ROᵢ includes the light-emitting elements of the first color 2R and the light-emitting elements of the third color 2G which are alternately arranged along the first direction X2, and the (i+1)-th light-emitting element row ROᵢ₊₁ includes the light-emitting elements of the second color 2B and the light-emitting elements of the third color 2G which are alternately arranged along the first direction X2. Moreover, in two adjacent light-emitting element columns CO along the first direction X2, light-emitting elements of different colors have different arrangements. For example, the j-th light-emitting element column COⱼ includes the light-emitting elements of the first color 2R and the light-emitting elements of the third color 2G which are alternately arranged along the second direction X3, and the (j+1)-th light-emitting element column COⱼ₊₁ includes the light-emitting elements of the second color 2B and the light-emitting elements of the third color 2G which are alternately arranged along the second direction X3. In this manner, the light-emitting elements of the first color 2R, the light-emitting elements of the second color 2B, and the light-emitting elements of the third color 2G can be uniformly and regularly arranged in the first direction X2 and the second direction X3. Moreover, the light-emitting element of the first color 2R, the light-emitting element of the second color 2B, and the light-emitting element of the third color 2G are each one of the red light-emitting element, the blue light-emitting element, and the green light-emitting element and are different from each other so that the light-emitting elements of different colors can be uniformly and regularly arranged in the first direction X2 and the second direction X3, ensuring that the light-emitting elements of different colors have a better display rendering effect and further ensuring the color display effect of the display panel. Meanwhile, a distribution density of the light-emitting elements of the third color 2G is greater than a distribution density of the light-emitting elements of the first color 2R and a distribution density of the light-emitting elements of the second color 2B, and the light-emitting elements of the third color 2G may be green light-emitting elements. Such a setting conforms to the physiological characteristic that human eyes are most sensitive to green light, ensuring that a display effect of higher visual clarity can be achieved with lower power consumption.

It is to be noted that the light-emitting element row and the light-emitting element column in the embodiments of the present application may each be understood as a light-emitting element set formed by multiple light-emitting elements arranged along a particular direction. For example, a light-emitting element set formed by multiple light-emitting elements arranged along the first direction X2 may be a light-emitting element row, and a light-emitting element set formed by multiple light-emitting elements arranged along the second direction X3 may be a light-emitting element column. In the subsequent embodiments, a light-emitting element set formed by multiple light-emitting elements arranged along a third direction (the direction X4 shown in the figure, where the third direction X4 is used hereinafter as an example for description) may also be a light-emitting element row, and a light-emitting element set formed by multiple light-emitting elements arranged along a fourth direction (the direction X5 shown in the figure, where the fourth direction X5 is used hereinafter as an example for description) may also be a light-emitting element column. An arrangement direction of multiple light-emitting elements in the light-emitting element row is not unique, and an arrangement direction of multiple light-emitting elements in the light-emitting element column is not unique.

Based on the preceding embodiments, with continued reference to FIGS. 1 and 6 to 12, the light-emitting elements of the first color 2R include first light-emitting elements of the first color 21R and second light-emitting elements of the first color 22R, the light-emitting elements of the second color 2B include first light-emitting elements of the second color 21B and second light-emitting elements of the second color 22B, and the light-emitting elements of the third color 2G include first light-emitting elements of the third color 21G and second light-emitting elements of the third color 22G; the first light-emitting elements 21 include the first light-emitting elements of the first color 21R, the first light-emitting elements of the second color 21B, and the first light-emitting elements of the third color 21G; the second light-emitting elements 22 include the second light-emitting elements of the first color 22R, the second light-emitting elements of the second color 22B, and the second light-emitting elements of the third color 22G; the display panel further includes multiple light-emitting element columns CO arranged along the third direction X4 and multiple light-emitting element rows RO arranged along the fourth direction X5, where the third direction X4 intersects the first direction X2, the second direction X3, and the fourth direction X5, and the fourth direction X5 intersects the first direction X2 and the second direction X3. In the same light-emitting element row, first light-emitting elements 21 and second light-emitting elements 22 of the same color are alternately arranged along the third direction X4.

As shown in FIGS. 1 and 6 to 12, in the embodiments of the present application, the first light-emitting elements 21 include the first light-emitting elements of the first color 21R, the first light-emitting elements of the second color 21B, and the first light-emitting elements of the third color 21G; and the second light-emitting elements 22 include the second light-emitting elements of the first color 22R, the second light-emitting elements of the second color 22B, and the second light-emitting elements of the third color 22G. That is, either the first light-emitting elements 21 or the second light-emitting elements 22 include multiple light-emitting elements of different colors. In this manner, the first light-emitting elements of the first color 21R, the first light-emitting elements of the second color 21B, the first light-emitting elements of the third color 21G, the second light-emitting elements of the first color 22R, the second light-emitting elements of the second color 22B, and the second light-emitting elements of the third color 22G all emit light in the sharing mode, achieving color display at the normal viewing angle and the large viewing angle in the sharing mode. In the privacy mode, the first light-emitting elements of the first color 21R, the first light-emitting elements of the second color 21B, the first light-emitting elements of the third color 21G, first light-emitting portions 22a in the second light-emitting elements of the first color 22R, first light-emitting portions 22a in the second light-emitting elements of the second color 22B, and first light-emitting portions 22a in the second light-emitting elements of the third color 22G emit light normally, achieving color display at the normal viewing angle in the privacy mode. Moreover, second light-emitting portions 22b in the second light-emitting elements of the first color 22R, second light-emitting portions 22b in the second light-emitting elements of the second color 22B, and second light-emitting portions 22b in the second light-emitting elements of the third color 22G emit no light so that light-emitting portions for light emission at the large viewing angle are missing in the privacy mode, and the display information of at least part of the light-emitting element groups is blurred or disordered at the large viewing angle in the privacy mode, achieving the confidentiality of display information of at least part of the light-emitting element groups at the large viewing angle, and implementing the anti-peeping function.

Moreover, in the same light-emitting element row RO, the first light-emitting elements 21 and the second light-emitting elements 22 of the same color are alternately arranged along the third direction X4. That is, the first light-emitting elements of the first color 21R and the second light-emitting elements of the first color 22R are alternately arranged in the third direction X4, and/or the first light-emitting elements of the second color 21B and the second light-emitting elements of the second color 22B are alternately arranged in the third direction X4, and/or the first light-emitting elements of the third color 21G and the second light-emitting elements of the third color 22G are alternately arranged in the third direction X4. In this manner, the first light-emitting elements 21 with light emission at the large viewing angle and the second light-emitting elements 22 without light emission at the large viewing angle are uniformly distributed in the third direction X4, ensuring that the display panel has good uniformity in luminescence brightness in the third direction X4, avoiding relatively high display brightness of a region where the first light-emitting elements 21 with light emission at the large viewing angle are concentrated and densely arranged in the third direction X4 and relatively low display brightness of a region where the second light-emitting elements 22 without light emission at the large viewing angle are concentrated and densely arranged in the third direction X4, that is, avoiding that a display region of the light-emitting display panel is non-uniform in brightness in the third direction X4, and ensuring good uniformity in the display brightness of the display panel.

In one or more embodiments, with continued reference to FIGS. 1 and 6 to 12, in the same light-emitting element column CO, a first group GR1 and a second group GR2 are alternately arranged along the fourth direction X5; and the first group GR1 includes two first light-emitting elements 21 of the same color, and the second group GR2 includes two second light-emitting elements 22 of the same color.

As shown in FIGS. 1 and 6 to 12, the same light-emitting element column CO includes multiple groups GR, and a group GR may be understood as a light-emitting element set formed by two light-emitting elements 2 of the same color which are arranged in the fourth direction X5. Moreover, two groups GR adjacent to each other in the fourth direction X5 include the first group GR1 and the second group GR2, light-emitting elements included in the first group GR1 and the second group GR2 have the same emitted color, the first group GR1 includes two first light-emitting elements 21, and the second group GR2 includes two second light-emitting elements 22. In this manner, in the same light-emitting element column CO formed by multiple light-emitting elements 2 arranged along the fourth direction X5, the first light-emitting elements 21 and the second light-emitting elements 22 of the same color are alternately arranged in pairs along the fourth direction X5. That is, the first group GR1 including two first light-emitting elements of the first color 21R and the second group GR2 including two second light-emitting elements of the first color 22R are alternately arranged in the fourth direction X5; and/or the first group GR1 including two first light-emitting elements of the second color 21B and the second group GR2 including two second light-emitting elements of the second color 22B are alternately arranged in the fourth direction X5; and/or the first group GR1 including two first light-emitting elements of the third color 21G and the second group GR2 including two second light-emitting elements of the third color 22G are alternately arranged in the fourth direction X5. In this manner, the first group GR1 including the first light-emitting elements 21 with light emission at the large viewing angle and the second group GR2 including the second light-emitting elements 22 without light emission at the large viewing angle are uniformly distributed in the fourth direction X5, ensuring that the display panel has good uniformity in luminescence brightness in the fourth direction X5, avoiding relatively high display brightness of a region where first groups GR1 including the first light-emitting elements 21 with light emission at the large viewing angle are concentrated and densely arranged in the fourth direction X5 and relatively low display brightness of a region where second groups GR2 including the second light-emitting elements 22 without light emission at the large viewing angle are concentrated and densely arranged in the fourth direction X5, that is, avoiding that the display region of the light-emitting display panel is non-uniform in brightness in the fourth direction X5, and ensuring good uniformity in the display brightness of the display panel.

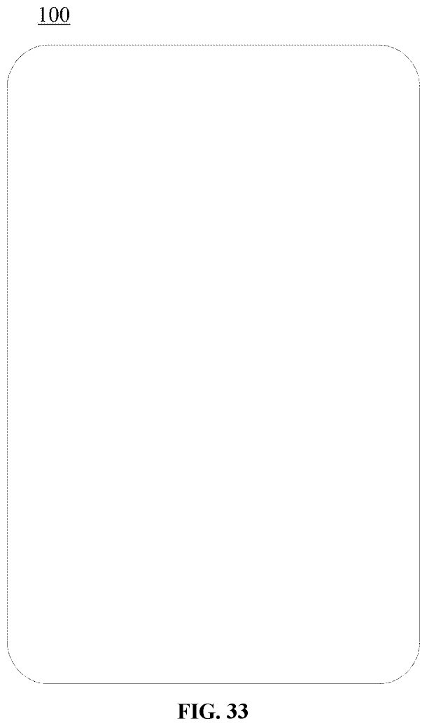

Based on the same inventive concept, embodiments of the present application provide a display device. FIG. 33 is a structure diagram of a display device according to embodiments of the present application. As shown in FIG. 33, the display device 100 includes the display panel of any preceding embodiment and thus has the same beneficial effects as any preceding embodiment. The details are not repeated here. The display device may be an electronic device such as a mobile phone, a computer, a smart wearable device (for example, a smartwatch), or an in-vehicle display device.

Apparently, the preceding embodiments of the present application are examples for clearly describing the present application and are not to limit embodiments of the present application. Those of ordinary skill in the art can make various apparent modifications, adaptations, and substitutions without departing from the scope of the present application. All embodiments of the present application cannot be and do not need to be exhausted herein. Any modifications, equivalent substitutions, and improvements made within the spirit and principle of the present application fall within the scope of the claims of the present application.

What is claimed is:

1. A display panel, comprising:
a substrate and a plurality of light-emitting elements on a side of the substrate; wherein the plurality of light-emitting elements comprise first light-emitting elements and second light-emitting elements, a second light-emitting element of the second light-emitting elements comprises a first light-emitting portion and a second light-emitting portion, and the second light-emitting portion surrounds at least part of the first light-emitting portion; and
a light-shielding structure and a pixel defining layer, wherein the light-shielding structure is located on a side of the plurality of light-emitting elements facing away from the substrate; the light-shielding structure comprises a first opening, a second opening, and a first light-shielding portion, and along a direction perpendicular to a plane where the substrate is located, the first opening at least partially overlaps a first light-emitting element of the first light-emitting elements, the second opening at least partially overlaps the first light-emitting portion, and the first light-shielding portion at least partially overlaps the second light-emitting portion; the pixel defining layer comprises a first pixel opening and a second pixel opening, the second pixel opening comprises a first pixel opening portion and a second pixel opening portion, and the second pixel opening portion surrounds at least part of the first pixel opening portion; at least part of the first light-emitting element is located within the first pixel opening; at least part of the first light-emitting portion is located within the first pixel opening portion; and along a direction parallel to the plane where the substrate is located, a minimum distance between an edge of the first opening and an edge of the first pixel opening is d1, a minimum distance between an edge of the second opening and an edge of the first pixel opening portion is d2, and d1>d2;
display modes of the display panel comprise a sharing mode and a privacy mode, wherein
in the sharing mode, the first light-emitting element, the first light-emitting portion, and the second light-emitting portion are all configured to emit light; and
in the privacy mode, the first light-emitting element and the first light-emitting portion are configured to emit light, and the second light-emitting portion is configured not to emit light.

2. The display panel according to claim 1, further comprising light-emitting elements of a first color, light-emitting elements of a second color, and light-emitting elements of a third color; wherein the light-emitting elements of the first color, the light-emitting elements of the second color, and the light-emitting elements of the third color are red light-emitting elements, blue light-emitting elements, and green light-emitting elements, respectively; and
the display panel further comprises a plurality of light-emitting element columns arranged along a first direction and a plurality of light-emitting element rows arranged along a second direction, and the first direction intersects the second direction; wherein an i-th light-emitting element row comprises light-emitting elements of the first color and light-emitting elements of the third color which are alternately arranged along the first direction; an (i+1)-th light-emitting element row comprises light-emitting elements of the second color and light-emitting elements of the third color which are alternately arranged along the first direction; a j-th light-emitting element column comprises light-emitting elements of the first color and light-emitting elements of the third color which are alternately arranged along the second direction; and a (j+1)-th light-emitting element column comprises light-emitting elements of the second color and light-emitting elements of the third color which are alternately arranged along the second direction, wherein i and j are each a positive integer.

3. The display panel according to claim 2, further comprising a plurality of light-emitting element columns arranged along a third direction and a plurality of light-emitting element rows arranged along a fourth direction, wherein the third direction intersects the first direction, the second direction, and the fourth direction, and the fourth direction intersects the first direction and the second direction; wherein
among the plurality of light-emitting element rows arranged along the fourth direction, a p-th light-emitting element row comprises light-emitting elements of the first color and light-emitting elements of the second color which are alternately arranged along the third direction, and a (p+1)-th light-emitting element row comprises a plurality of light-emitting elements of the third color which are arranged along the third direction; and among the plurality of light-emitting element columns arranged along the third direction, a q-th light-emitting element column comprises light-emitting elements of the first color and light-emitting elements of the second color which are alternately arranged along the fourth direction, and a (q+1)-th light-emitting element column comprises a plurality of light-emitting elements of the third color which are arranged along the fourth direction, wherein p and q are each a positive integer.

4. The display panel according to claim 2, wherein the light-emitting elements of the first color comprise first light-emitting elements of the first color and second light-emitting elements of the first color, the light-emitting elements of the second color comprise first light-emitting elements of the second color and second light-emitting elements of the second color, and the light-emitting elements of the third color comprise first light-emitting elements of the third color and second light-emitting elements of the third color; the first light-emitting elements comprise the first light-emitting elements of the first color, the first light-emitting elements of the second color, and the first light-emitting elements of the third color; and the second light-emitting elements comprise the second light-emitting elements of the first color, the second light-emitting elements of the second color, and the second light-emitting elements of the third color;
the display panel further comprises a plurality of light-emitting element columns arranged along a third direction and a plurality of light-emitting element rows arranged along a fourth direction, wherein the third direction intersects the first direction, the second direction, and the fourth direction, and the fourth direction intersects the first direction and the second direction; and
in a same light-emitting element row among the plurality of light-emitting element rows arranged along the fourth direction, first light-emitting elements and second light-emitting elements of a same color are alternately arranged along the third direction.

5. The display panel according to claim 4, wherein among the plurality of light-emitting element rows arranged along the fourth direction,
in a p-th light-emitting element row, first light-emitting elements of the first color and second light-emitting elements of the first color are alternately arranged along the third direction, and first light-emitting elements of the second color and second light-emitting elements of the second color are alternately arranged along the third direction, wherein p is a positive integer; and
in a (p+1)-th light-emitting element row, first light-emitting elements of the third color and second light-emitting elements of the third color are alternately arranged along the third direction.

6. The display panel according to claim 4, wherein
in a same light-emitting element column among the plurality of light-emitting element columns arranged along the third direction, a first group and a second group are alternately arranged along the fourth direction; wherein the first group comprises two first light-emitting elements of a same color, and the second group comprises two second light-emitting elements of the same color; and
the first group comprises a first subgroup, a second subgroup, and a third subgroup, and the second group comprises a fourth subgroup, a fifth subgroup, and a sixth subgroup;
wherein among the plurality of light-emitting element columns arranged along the third direction,
in a q-th light-emitting element column, the first subgroup and the fourth subgroup are alternately arranged along the fourth direction; the first subgroup comprises two first light-emitting elements of the first color which are adjacent to each other along the fourth direction; and the fourth subgroup comprises two second light-emitting elements of the first color which are adjacent to each other along the fourth direction; wherein q is a positive integer;
in the q-th light-emitting element column, the second subgroup and the fifth subgroup are alternately arranged along the fourth direction; the second subgroup comprises two first light-emitting elements of the second color which are adjacent to each other along the fourth direction; and the fifth subgroup comprises two second light-emitting elements of the second color which are adjacent to each other along the fourth direction; and
in a (q+1)-th light-emitting element column, the third subgroup and the sixth subgroup are alternately arranged along the fourth direction; the third subgroup comprises two first light-emitting elements of the third color which are adjacent to each other along the fourth direction; and the sixth subgroup comprises two second light-emitting elements of the third color which are adjacent to each other along the fourth direction.

7. The display panel according to claim 4, further comprising a first light-emitting group, a second light-emitting group, a third light-emitting group, and a fourth light-emitting group; wherein
the first light-emitting group comprises four light-emitting elements of the first color which are adjacent to each other along the first direction, and along the first direction, two adjacent first light-emitting elements of the first color are located between two adjacent second light-emitting elements of the first color; and the second light-emitting group comprises four light-emitting elements of the first color which are adjacent to each other along the first direction, and along the first direction, two adjacent second light-emitting elements of the first color are located between two adjacent first light-emitting elements of the first color;
the third light-emitting group comprises four first light-emitting elements of the first color which are adjacent to each other along the second direction; and the fourth light-emitting group comprises four second light-emitting elements of the first color which are adjacent to each other along the second direction;
in the i-th light-emitting element row, the first light-emitting group and the second light-emitting group are alternately arranged along the first direction; and
in the j-th light-emitting element column, the third light-emitting group and the fourth light-emitting group are alternately arranged along the second direction.

8. The display panel according to claim 4, further comprising a fifth light-emitting group, a sixth light-emitting group, a seventh light-emitting group, and an eighth light-emitting group; wherein
the fifth light-emitting group comprises four first light-emitting elements of the second color which are adjacent to each other along the first direction; and the sixth light-emitting group comprises four second light-emitting elements of the second color which are adjacent to each other along the first direction;
the seventh light-emitting group comprises four light-emitting elements of the second color which are adjacent to each other along the second direction, and along the second direction, two adjacent first light-emitting elements of the second color are located between two adjacent second light-emitting elements of the second color; the eighth light-emitting group comprises four light-emitting elements of the second color which are adjacent to each other along the second direction, and along the second direction, two adjacent second light-emitting elements of the second color are located between two adjacent first light-emitting elements of the second color;
in the (i+1)-th light-emitting element row, the fifth light-emitting group and the sixth light-emitting group are alternately arranged along the first direction; and
in the (j+1)-th light-emitting element column, the seventh light-emitting group and the eighth light-emitting group are alternately arranged along the second direction.

9. The display panel according to claim 4, further comprising a ninth light-emitting group, a tenth light-emitting group, an eleventh light-emitting group, and a twelfth light-emitting group; wherein
the ninth light-emitting group comprises two first light-emitting elements of the third color which are adjacent to each other along the first direction; and the tenth light-emitting group comprises two second light-emitting elements of the third color which are adjacent to each other along the first direction;
the eleventh light-emitting group comprises two first light-emitting elements of the third color which are adjacent to each other along the second direction; and the twelfth light-emitting group comprises two second light-emitting elements of the third color which are adjacent to each other along the second direction;
in the i-th light-emitting element row, the ninth light-emitting group and the tenth light-emitting group are alternately arranged along the first direction;
in the (i+1)-th light-emitting element row, the ninth light-emitting group and the tenth light-emitting group are alternately arranged along the first direction;
in the j-th light-emitting element column, the eleventh light-emitting group and the twelfth light-emitting group are alternately arranged along the second direction; and
in the (j+1)-th light-emitting element column, the eleventh light-emitting group and the twelfth light-emitting group are alternately arranged along the second direction.

10. The display panel according to claim 1, wherein the second light-emitting portion surrounds the first light-emitting portion.

11. The display panel according to claim 1, further comprising a plurality of pixel circuits located on a side of the substrate; wherein
the plurality of pixel circuits comprise a first pixel circuit, a second pixel circuit, and a third pixel circuit, the first pixel circuit is electrically connected to the first light-emitting element, the second pixel circuit is electrically connected to the first light-emitting portion, and the third pixel circuit is electrically connected to the second light-emitting portion; and
the first pixel circuit, the second pixel circuit, and the third pixel circuit are independently disposed.

12. The display panel according to claim 1, further comprising a plurality of pixel circuits located on a side of the substrate; wherein
the plurality of pixel circuits comprise a first pixel circuit and a fourth pixel circuit, the first pixel circuit is electrically connected to the first light-emitting element, and the fourth pixel circuit is electrically connected to the first light-emitting portion and the second light-emitting portion, separately;
the display panel further comprises a switch unit and a control module, the switch unit is connected in series between the fourth pixel circuit and the second light-emitting portion, and the control module is electrically connected to the switch unit; and
the control module is configured to control the switch unit to be turned on in the sharing mode to conduct the fourth pixel circuit with the second light-emitting portion; and the control module is further configured to control the switch unit to be turned off in the privacy mode to disconnect the fourth pixel circuit from the second light-emitting portion.

13. The display panel according to claim 1, wherein for a first light-emitting element and a second light-emitting element having a same emitted color, a pixel opening area of the first light-emitting element is S1, a pixel opening area of the first light-emitting portion is S2, and a pixel opening area of the second light-emitting portion is S3;
wherein S1>S3, S2>S3, and 80% ≤S1/S2 ≤120%.

14. The display panel according to claim 1, wherein a shape of at least one of the first pixel opening, the first pixel opening portion, or the second pixel opening comprises a circle.

15. The display panel according to claim 3, further comprising pixel circuits and signal lines located on a side of the substrate; wherein
the signal lines comprise scanning signal lines and data signal lines, and each of the pixel circuits is electrically connected to one of the scanning signal lines, one of the data signal lines, and one of the plurality of light-emitting elements, separately; and
the scanning signal lines extend along the third direction, and the data signal lines extend along the fourth direction.

16. The display panel according to claim 1, further comprising a touch structure, a color resist structure, and a black light-shielding layer which are located on the side of the plurality of light-emitting elements facing away from the substrate, wherein the color resist structure comprises color resist layers of different colors; and
the light-shielding structure comprises at least one of the touch structure, at least two stacked color resist layers of different colors, or the black light-shielding layer.

17. A display panel, comprising:
a substrate and a plurality of light-emitting elements on a side of the substrate;
wherein the plurality of light-emitting elements comprise first light-emitting elements and second light-emitting elements, a second light-emitting element of the second light-emitting elements comprises a first light-emitting portion and a second light-emitting portion, and the second light-emitting portion surrounds at least part of the first light-emitting portion;
a maximum light-emitting viewing angle of a first light-emitting element of the first light-emitting elements is greater than a maximum light-emitting viewing angle of the first light-emitting portion, and a minimum light-emitting viewing angle of the second light-emitting portion is greater than a minimum light-emitting viewing angle of the first light-emitting element and a minimum light-emitting viewing angle of the first light-emitting portion;
display modes of the display panel comprise a sharing mode and a privacy mode, wherein
in the sharing mode, the first light-emitting element, the first light-emitting portion, and the second light-emitting portion are all configured to emit light; and
in the privacy mode, the first light-emitting element and the first light-emitting portion are configured to emit light, and the second light-emitting portion is configured not to emit light.

18. The display panel according to claim 17, further comprising light-emitting elements of a first color, light-emitting elements of a second color, and light-emitting elements of a third color; wherein the light-emitting elements of the first color, the light-emitting elements of the second color, and the light-emitting elements of the third color are red light-emitting elements, blue light-emitting elements, and green light-emitting elements, respectively; and
the display panel further comprises a plurality of light-emitting element columns arranged along a first direction and a plurality of light-emitting element rows arranged along a second direction, and the first direction intersects the second direction; wherein an i-th light-emitting element row comprises light-emitting elements of the first color and light-emitting elements of the third color which are alternately arranged along the first direction; an (i+1)-th light-emitting element row comprises light-emitting elements of the second color and light-emitting elements of the third color which are alternately arranged along the first direction; a j-th light-emitting element column comprises light-emitting elements of the first color and light-emitting elements of the third color which are alternately arranged along the second direction; and a (j+1)-th light-emitting element column comprises light-emitting elements of the second color and light-emitting elements of the third color which are alternately arranged along the second direction, wherein i and j are each a positive integer.

19. The display panel according to claim 18, wherein the light-emitting elements of the first color comprise first light-emitting elements of the first color and second light-emitting elements of the first color, the light-emitting elements of the second color comprise first light-emitting elements of the second color and second light-emitting elements of the second color, and the light-emitting elements of the third color comprise first light-emitting elements of the third color and second light-emitting elements of the third color; the first light-emitting elements comprise the first light-emitting elements of the first color, the first light-emitting elements of the second color, and the first light-emitting elements of the third color; and the second light-emitting elements comprise the second light-emitting elements of the first color, the second light-emitting elements of the second color, and the second light-emitting elements of the third color;
the display panel further comprises a plurality of light-emitting element columns arranged along a third direction and a plurality of light-emitting element rows arranged along a fourth direction, wherein the third direction intersects the first direction, the second direction, and the fourth direction, and the fourth direction intersects the first direction and the second direction; and
in a same light-emitting element row among the plurality of light-emitting element rows arranged along the fourth direction, first light-emitting elements and second light-emitting elements of a same color are alternately arranged along the third direction.

20. The display panel according to claim 19, wherein
in a same light-emitting element column among the plurality of light-emitting element columns arranged along the third direction, a first group and a second group are alternately arranged along the fourth direction; and
the first group comprises two first light-emitting elements of a same color, and the second group comprises two second light-emitting elements of the same color.
